(19) United States
(12) Patent Application Publication
(10) Pub. No.: US 2024/0072764 A1
(43) Pub. Date: Feb. 29, 2024

(54) BULK ACOUSTIC WAVE RESONANT STRUCTURE AND MANUFACTURING METHOD THEREFOR

(71) Applicant: WUHAN YANXI MICRO COMPONENTS CO., LTD., Wuhan (CN)

(72) Inventors: Dapeng ZHANG, Wuhan (CN); Zhiwei KOH, Wuhan (CN); Re-ching LIN, Wuhan (CN); Zhi DUAN, Wuhan (CN)

(73) Assignee: WUHAN YANXI MICRO COMPONENTS CO., LTD., Wuhan (CN)

(21) Appl. No.: 18/178,357

(22) Filed: Mar. 3, 2023

Related U.S. Application Data
(63) Continuation of application No. PCT/CN2021/120744, filed on Sep. 26, 2021.

(30) Foreign Application Priority Data
Feb. 22, 2021 (CN) 202110199093.5

(51) Int. Cl. H03H 9/17; H03H 3/02

(52) U.S. Cl. CPC H03H 9/172; H03H 3/02

(57) ABSTRACT

A bulk acoustic wave resonant structure includes a substrate, and a reflection structure, a first electrode layer, a piezoelectric layer and a second electrode layer, which are sequentially stacked on the substrate, wherein ring-shaped grooves are provided in the piezoelectric layer; and the grooves are located in an active area and are close to an edge of the active area.

### CROSS-REFERENCE TO RELATED APPLICATIONS

This is a continuation of International Application No. PCT/CN2021/120744 filed on Sep. 26, 2021, which claims priority to Chinese Patent Application No. 202110199093.5 filed on Feb. 22, 2021. The disclosures of the above-referenced applications are hereby incorporated by reference in their entirety.

### BACKGROUND

Bulk Acoustic Wave (BAW) resonators (also refer to as “bulk acoustic wave resonance structures”) have advantages such as small size and high quality factor (Q), and are widely used in the mobile communication technology, such as filters or diplexers in mobile terminals. Structural features of the bulk acoustic wave resonance structure and methods for manufacturing the bulk acoustic wave resonance structure in some implementations can be found in CN111030627A and CN111030629A.

However, in the mobile terminals, multiple frequency bands can be used at the same time, which requires steeper skirts and smaller insertion loss of the filters or the duplexers. Performance of a filter is determined by a resonator constituting the filter, and increasing the Q value of the resonator can implement the steep skirt and small insertion loss. At the same time, large parasitic resonance may also adversely affect the performance of the filters or the duplexers. How to reduce the parasitic resonance and improve the Q value of the bulk acoustic wave resonator has become an urgent problem to be solved.

### SUMMARY

Embodiment of the application relates to the technical field of semiconductor, and in particular to a bulk acoustic wave resonance structure and a method for manufacturing the same.

In order to solve the related technical problems, embodiments of the present disclosure provide a bulk acoustic wave resonance structure and a method for manufacturing the same.

A first aspect of the embodiments of the present disclosure provide a bulk acoustic wave resonance structure, which includes a substrate and includes a reflective structure, a first electrode layer, a piezoelectric layer and a second electrode layer stacked on the substrate in sequence. The piezoelectric layer is provided with at least one annular groove, and the at least one annular groove is located in an active area and close to an edge of the active area.

A second aspect of the embodiments of the present disclosure provides a method for manufacturing a bulk acoustic wave resonance structure, which includes the following operations. A reflective structure is formed on a substrate. A first electrode layer is formed on the reflective structure. A piezoelectric layer is formed on the first electrode layer. At least one annular groove is formed in the piezoelectric layer. The at least one annular groove is located in an active area and close to an edge of the active area. A second electrode layer is formed on the piezoelectric layer.

In the embodiments of the present disclosure, at least one annular groove is provided at an edge of an active area of the piezoelectric layer. The groove can prevent transversal shear waves generated by a bulk acoustic wave resonator when stimulated by an electric field from propagating to the external region, limit energy to longitudinal waves in the active area, reduce the energy leakage and parasitic resonance, and increase the Q value.

### BRIEF DESCRIPTION OF THE DRAWINGS

FIG. 1 is a diagram of sound waves generated by the piezoelectric effect in a piezoelectric layer of a bulk acoustic wave resonance structure according to an embodiment of the present disclosure.

FIG. 2A is a first diagram of simulation results of vibration modes of a bulk acoustic wave resonator in cases that a piezoelectric layer of a bulk acoustic wave resonance structure has no grooves and has grooves respectively according to an embodiment of the present disclosure.

FIG. 2B is a second diagram of simulation results of vibration modes of a bulk acoustic wave resonator in cases that a piezoelectric layer of a bulk acoustic wave resonance structure has no grooves and has grooves respectively according to an embodiment of the present disclosure.

FIG. 3A is a first diagram of test results of frequency quality factors and impedances of a bulk acoustic wave resonator in cases that a piezoelectric layer of a bulk acoustic wave resonance structure has no grooves and has grooves respectively according to an embodiment of the present disclosure.

FIG. 3B is a second diagram of test results of frequency quality factors and impedances of a bulk acoustic wave resonator in cases that a piezoelectric layer of a bulk acoustic wave resonance structure has no grooves and has grooves respectively according to an embodiment of the present disclosure.

FIG. 4 is a diagram of a smith chart in cases that a bulk acoustic wave resonance structure has no grooves and has grooves respectively according to an embodiment of the present disclosure.

FIG. 5A is a top view diagram of a bulk acoustic wave resonance structure 100 according to an embodiment of the present disclosure.

FIG. 5B is a cross-sectional diagram of the bulk acoustic wave resonance structure 100 in a direction A illustrated in FIG. 5A.

FIG. 6A is a first diagram of influences on the lateral parasitic mode and the Q value when grooves are arranged at different positions of piezoelectric layer according to embodiments of the present disclosure.

FIG. 6B is a second diagram of influences on the lateral parasitic mode and the Q value when grooves are arranged at different positions of piezoelectric layer according to embodiments of the present disclosure.

FIG. 6C is a third diagram of influences on the lateral parasitic mode and the Q value when grooves are arranged at different positions of piezoelectric layer according to embodiments of the present disclosure.

FIG. 6D is a fourth diagram of influences on the lateral parasitic mode and the Q value when grooves are arranged at different positions of piezoelectric layer according to embodiments of the present disclosure.

FIG. 6E is a fifth diagram of influences on the lateral parasitic mode and the Q value when grooves are arranged at different positions of piezoelectric layer according to embodiments of the present disclosure.

FIG. 6F is a sixth diagram of influences on the lateral parasitic mode and the Q value when grooves are arranged at different positions of piezoelectric layer according to embodiments of the present disclosure.

FIG. 6G is a seventh diagram of influences on the lateral parasitic mode and the Q value when grooves are arranged at different positions of piezoelectric layer according to embodiments of the present disclosure.

FIG. 6H is an eighth diagram of influences on the lateral parasitic mode and the Q value when grooves are arranged at different positions of piezoelectric layer according to embodiments of the present disclosure.

FIG. 6I is a ninth diagram of influences on the lateral parasitic mode and the Q value when grooves are arranged at different positions of piezoelectric layer according to embodiments of the present disclosure.

FIG. 6J is a tenth diagram of influences on the lateral parasitic mode and the Q value when grooves are arranged at different positions of piezoelectric layer according to embodiments of the present disclosure.

FIG. 6K is an eleventh diagram of influences on the lateral parasitic mode and the Q value when grooves are arranged at different positions of piezoelectric layer according to embodiments of the present disclosure.

FIG. 6L is a twelfth diagram of influences on the lateral parasitic mode and the Q value when grooves are arranged at different positions of piezoelectric layer according to embodiments of the present disclosure.

FIG. 7A is a first diagram of influences on the lateral parasitic mode and the Q value when different numbers of grooves are provided according to embodiments of the present disclosure.

FIG. 7B is a second diagram of influences on the lateral parasitic mode and the Q value when different numbers of grooves are provided according to embodiments of the present disclosure.

FIG. 7C is a third diagram of influences on the lateral parasitic mode and the Q value when different numbers of grooves are provided according to embodiments of the present disclosure.

FIG. 7D is a fourth diagram of influences on the lateral parasitic mode and the Q value when different numbers of grooves are provided according to embodiments of the present disclosure.

FIG. 7E is a fifth diagram of influences on the lateral parasitic mode and the Q value when different numbers of grooves are provided according to embodiments of the present disclosure.

FIG. 7F is a sixth diagram of influences on the lateral parasitic mode and the Q value when different numbers of grooves are provided according to embodiments of the present disclosure.

FIG. 7G is a seventh diagram of influences on the lateral parasitic mode and the Q value when different numbers of grooves are provided according to embodiments of the present disclosure.

FIG. 7H is an eighth diagram of influences on the lateral parasitic mode and the Q value when different numbers of grooves are provided according to embodiments of the present disclosure.

FIG. 7I is a ninth diagram of influences on the lateral parasitic mode and the Q value when different numbers of grooves are provided according to embodiments of the present disclosure.

FIG. 7J is a tenth diagram of influences on the lateral parasitic mode and the Q value when different numbers of grooves are provided according to embodiments of the present disclosure.

FIG. 7K is an eleventh diagram of influences on the lateral parasitic mode and the Q value when different numbers of grooves are provided according to embodiments of the present disclosure.

FIG. 7L is a twelfth diagram of influences on the lateral parasitic mode and the Q value when different numbers of grooves are provided according to embodiments of the present disclosure.

FIG. 7M is a thirteenth diagram of influences on the lateral parasitic mode and the Q value when different numbers of grooves are provided according to embodiments of the present disclosure.

FIG. 7N is a fourteenth diagram of influences on the lateral parasitic mode and the Q value when different numbers of grooves are provided according to embodiments of the present disclosure.

FIG. 7O is a fifteenth diagram of influences on the lateral parasitic mode and the Q value when different numbers of grooves are provided according to embodiments of the present disclosure.

FIG. 8A is a first cross-sectional diagram of a film bulk acoustic wave resonance structure according to embodiments of the present disclosure.

FIG. 8B is a second cross-sectional diagram of a film bulk acoustic wave resonance structure according to embodiments of the present disclosure.

FIG. 8C is a third cross-sectional diagram of a film bulk acoustic wave resonance structure according to embodiments of the present disclosure.

FIG. 9 is a diagram of grooves filled with an amorphous material according to an embodiment of the present disclosure.

FIG. 10 is a diagram of grooves with openings facing a bottom surface of a piezoelectric layer according to an embodiment of the present disclosure.

FIG. 11A is a first diagram of influences on the lateral parasitic mode and the Q value when opening depths of grooves meet different rules according to embodiments of the present disclosure.

FIG. 11B is a second diagram of influences on the lateral parasitic mode and the Q value when opening depths of grooves meet different rules according to embodiments of the present disclosure.

FIG. 11C is a third diagram of influences on the lateral parasitic mode and the Q value when opening depths of grooves meet different rules according to embodiments of the present disclosure.

FIG. 11D is a fourth diagram of influences on the lateral parasitic mode and the Q value when opening depths of grooves meet different rules according to embodiments of the present disclosure.

FIG. 11E is a fifth diagram of influences on the lateral parasitic mode and the Q value when opening depths of grooves meet different rules according to embodiments of the present disclosure.

FIG. 11F is a sixth diagram of influences on the lateral parasitic mode and the Q value when opening depths of grooves meet different rules according to embodiments of the present disclosure.

FIG. 11G is a seventh diagram of influences on the lateral parasitic mode and the Q value when opening depths of grooves meet different rules according to embodiments of the present disclosure.

FIG. 11H is an eighth diagram of influences on the lateral parasitic mode and the Q value when opening depths of grooves meet different rules according to embodiments of the present disclosure.

FIG. 11I is a ninth diagram of influences on the lateral parasitic mode and the Q value when opening depths of grooves meet different rules according to embodiments of the present disclosure.

FIG. 11J is a tenth diagram of influences on the lateral parasitic mode and the Q value when opening depths of grooves meet different rules according to embodiments of the present disclosure.

FIG. 11K is an eleventh diagram of influences on the lateral parasitic mode and the Q value when opening depths of grooves meet different rules according to embodiments of the present disclosure.

FIG. 11L is a twelfth diagram of influences on the lateral parasitic mode and the Q value when opening depths of grooves meet different rules according to embodiments of the present disclosure.

FIG. 11M is a thirteenth diagram of influences on the lateral parasitic mode and the Q value when opening depths of grooves meet different rules according to embodiments of the present disclosure.

FIG. 11N is a fourteenth diagram of influences on the lateral parasitic mode and the Q value when opening depths of grooves meet different rules according to embodiments of the present disclosure.

FIG. 11O is a fifteenth diagram of influences on the lateral parasitic mode and the Q value when opening depths of grooves meet different rules according to embodiments of the present disclosure.

FIG. 12A is a first diagram of test results of relationship between impedance and frequency of a bulk acoustic wave resonator for different opening depths according to embodiments of the present disclosure.

FIG. 12B is a second diagram of test results of relationship between impedance and frequency of a bulk acoustic wave resonator for different opening depths according to embodiments of the present disclosure.

FIG. 12C is a third diagram of test results of relationship between impedance and frequency of a bulk acoustic wave resonator for different opening depths according to embodiments of the present disclosure.

FIG. 12D is a fourth diagram of test results of relationship between impedance and frequency of a bulk acoustic wave resonator for different opening depths according to embodiments of the present disclosure.

FIG. 12E is a fifth diagram of test results of relationship between impedance and frequency of a bulk acoustic wave resonator for different opening depths according to embodiments of the present disclosure.

FIG. 12F is a sixth diagram of test results of relationship between impedance and frequency of a bulk acoustic wave resonator for different opening depths according to embodiments of the present disclosure.

FIG. 12G is a seventh diagram of test results of relationship between impedance and frequency of a bulk acoustic wave resonator for different opening depths according to embodiments of the present disclosure.

FIG. 12H is an eighth diagram of test results of relationship between impedance and frequency of a bulk acoustic wave resonator for different opening depths according to embodiments of the present disclosure.

FIG. 13A is a first diagram of test results of smith charts of a bulk acoustic wave resonator for different opening depths according to embodiments of the present disclosure.

FIG. 13B is a second diagram of test results of smith charts of a bulk acoustic wave resonator for different opening depths according to embodiments of the present disclosure.

FIG. 13C is a third diagram of test results of smith charts of a bulk acoustic wave resonator for different opening depths according to embodiments of the present disclosure.

FIG. 13D is a fourth diagram of test results of smith charts of a bulk acoustic wave resonator for different opening depths according to embodiments of the present disclosure.

FIG. 13E is a fifth diagram of test results of smith charts of a bulk acoustic wave resonator for different opening depths according to embodiments of the present disclosure.

FIG. 13F is a sixth diagram of test results of smith charts of a bulk acoustic wave resonator for different opening depths according to embodiments of the present disclosure.

FIG. 13G is a seventh diagram of test results of smith charts of a bulk acoustic wave resonator for different opening depths according to embodiments of the present disclosure.

FIG. 13H is an eighth diagram of test results of smith charts of a bulk acoustic wave resonator for different opening depths according to embodiments of the present disclosure.

FIG. 14 is a top view diagram of another bulk acoustic wave resonance structure according to an embodiment of the present disclosure.

FIG. 15 is a diagram of a smith chart in cases that a bulk acoustic wave resonance structure has no frame or has a frame according to an embodiment of the present disclosure.

FIG. 16 is a cross-sectional diagram of yet another bulk acoustic wave resonance structure according to an embodiment of the present disclosure.

FIG. 17A is a first diagram of influences on the lateral parasitic mode and the Q value when grooves are arranged at different positions of the piezoelectric layer according to embodiments of the present disclosure.

FIG. 17B is a second diagram of influences on the lateral parasitic mode and the Q value when grooves are arranged at different positions of the piezoelectric layer according to embodiments of the present disclosure.

FIG. 17C is a third diagram of influences on the lateral parasitic mode and the Q value when grooves are arranged at different positions of the piezoelectric layer according to embodiments of the present disclosure.

FIG. 17D is a fourth diagram of influences on the lateral parasitic mode and the Q value when grooves are arranged at different positions of the piezoelectric layer according to embodiments of the present disclosure.

FIG. 17E is a fifth diagram of influences on the lateral parasitic mode and the Q value when grooves are arranged at different positions of the piezoelectric layer according to embodiments of the present disclosure.

FIG. 17F is a sixth diagram of influences on the lateral parasitic mode and the Q value when grooves are arranged at different positions of the piezoelectric layer according to embodiments of the present disclosure.

FIG. 17G is a seventh diagram of influences on the lateral parasitic mode and the Q value when grooves are arranged at different positions of the piezoelectric layer according to embodiments of the present disclosure.

FIG. 17H is an eighth diagram of influences on the lateral parasitic mode and the Q value when grooves are arranged at different positions of the piezoelectric layer according to embodiments of the present disclosure.

FIG. 18A is a first diagram of influences on the lateral parasitic mode and the Q value when different numbers of grooves are provided according to embodiments of the present disclosure.

FIG. 18B is a second diagram of influences on the lateral parasitic mode and the Q value when different numbers of grooves are provided according to embodiments of the present disclosure.

FIG. 18C is a third diagram of influences on the lateral parasitic mode and the Q value when different numbers of grooves are provided according to embodiments of the present disclosure.

FIG. 18D is a fourth diagram of influences on the lateral parasitic mode and the Q value when different numbers of grooves are provided according to embodiments of the present disclosure.

FIG. 18E is a fifth diagram of influences on the lateral parasitic mode and the Q value when different numbers of grooves are provided according to embodiments of the present disclosure.

FIG. 18F is a sixth diagram of influences on the lateral parasitic mode and the Q value when different numbers of grooves are provided according to embodiments of the present disclosure.

FIG. 18G is a seventh diagram of influences on the lateral parasitic mode and the Q value when different numbers of grooves are provided according to embodiments of the present disclosure.

FIG. 18H is an eighth diagram of influences on the lateral parasitic mode and the Q value when different numbers of grooves are provided according to embodiments of the present disclosure.

FIG. 18I is a ninth diagram of influences on the lateral parasitic mode and the Q value when different numbers of grooves are provided according to embodiments of the present disclosure.

FIG. 18J is a tenth diagram of influences on the lateral parasitic mode and the Q value when different numbers of grooves are provided according to embodiments of the present disclosure.

FIG. 18K is an eleventh diagram of influences on the lateral parasitic mode and the Q value when different numbers of grooves are provided according to embodiments of the present disclosure.

FIG. 18L is a twelfth diagram of influences on the lateral parasitic mode and the Q value when different numbers of grooves are provided according to embodiments of the present disclosure.

FIG. 18M is a thirteenth diagram of influences on the lateral parasitic mode and the Q value when different numbers of grooves are provided according to embodiments of the present disclosure.

FIG. 18N is a fourteenth diagram of influences on the lateral parasitic mode and the Q value when different numbers of grooves are provided according to embodiments of the present disclosure.

FIG. 18O is a fifteenth diagram of influences on the lateral parasitic mode and the Q value when different numbers of grooves are provided according to embodiments of the present disclosure.

FIG. 19A is a first diagram of influences on the lateral parasitic mode and the Q value when opening depths of grooves meet different rules according to embodiments of the present disclosure.

FIG. 19B is a second diagram of influences on the lateral parasitic mode and the Q value when opening depths of grooves meet different rules according to embodiments of the present disclosure.

FIG. 19C is a third diagram of influences on the lateral parasitic mode and the Q value when opening depths of grooves meet different rules according to embodiments of the present disclosure.

FIG. 19D is a fourth diagram of influences on the lateral parasitic mode and the Q value when opening depths of grooves meet different rules according to embodiments of the present disclosure.

FIG. 19E is a fifth diagram of influences on the lateral parasitic mode and the Q value when opening depths of grooves meet different rules according to embodiments of the present disclosure.

FIG. 19F is a sixth diagram of influences on the lateral parasitic mode and the Q value when opening depths of grooves meet different rules according to embodiments of the present disclosure.

FIG. 19G is a seventh diagram of influences on the lateral parasitic mode and the Q value when opening depths of grooves meet different rules according to embodiments of the present disclosure.

FIG. 19H is an eighth diagram of influences on the lateral parasitic mode and the Q value when opening depths of grooves meet different rules according to embodiments of the present disclosure.

FIG. 19I is a ninth diagram of influences on the lateral parasitic mode and the Q value when opening depths of grooves meet different rules according to embodiments of the present disclosure.

FIG. 19J is a tenth diagram of influences on the lateral parasitic mode and the Q value when opening depths of grooves meet different rules according to embodiments of the present disclosure.

FIG. 19K is an eleventh diagram of influences on the lateral parasitic mode and the Q value when opening depths of grooves meet different rules according to embodiments of the present disclosure.

FIG. 19L is a twelfth diagram of influences on the lateral parasitic mode and the Q value when opening depths of grooves meet different rules according to embodiments of the present disclosure.

FIG. 20 is a diagram of an implementation flow of a method for manufacturing a bulk acoustic wave resonance structure according to an embodiment of the present disclosure.

FIG. 21A is a first cross-sectional diagram of a flow of a method for manufacturing a bulk acoustic wave resonance structure according to embodiments of the present disclosure.

FIG. 21B is a second cross-sectional diagram of a flow of a method for manufacturing a bulk acoustic wave resonance structure according to embodiments of the present disclosure.

FIG. 21C is a third cross-sectional diagram of a flow of a method for manufacturing a bulk acoustic wave resonance structure according to embodiments of the present disclosure.

FIG. 21D is a fourth cross-sectional diagram of a flow of a method for manufacturing a bulk acoustic wave resonance structure according to embodiments of the present disclosure.

FIG. 21E is a fifth cross-sectional diagram of a flow of a method for manufacturing a bulk acoustic wave resonance structure according to embodiments of the present disclosure.

FIG. 21F is a sixth cross-sectional diagram of a flow of a method for manufacturing a bulk acoustic wave resonance structure according to embodiments of the present disclosure.

FIG. 22A is a first cross-sectional diagram of a flow of another method for manufacturing a bulk acoustic wave resonance structure according to embodiments of the present disclosure.

FIG. 22B is a second cross-sectional diagram of a flow of another method for manufacturing a bulk acoustic wave resonance structure according to embodiments of the present disclosure.

FIG. 22C is a third cross-sectional diagram of a flow of another method for manufacturing a bulk acoustic wave resonance structure according to embodiments of the present disclosure.

FIG. 22D is a fourth cross-sectional diagram of a flow of another method for manufacturing a bulk acoustic wave resonance structure according to embodiments of the present disclosure.

### DETAILED DESCRIPTION

Technical solutions of the present disclosure will be described in more detail below with reference to the drawings and embodiments. Although exemplary embodiments of the present disclosure are illustrated in the drawings, it should be understood that the present disclosure may be implemented in various forms and should not be limited by the embodiments set forth herein. Rather, these embodiments are provided to enable a more thorough understanding of the disclosure and to enable the full scope of the present disclosure to be conveyed to those skilled in the art.

The present disclosure will be described in more detail by way of examples in the following paragraphs with reference to the drawings. Advantages and features of the present disclosure will become clearer according to the following description and claims. It should be noted that all the drawings are illustrated in simplified forms with imprecise proportions, and are only used to conveniently and clearly assist in illustrating the embodiments of the present disclosure.

In the embodiments of the present disclosure, terms “first”, “second”, and the like are used to distinguish similar objects and are not intended to describe a particular order or priority.

It should be noted that the technical proposals described in the embodiment of the present disclosure can be arbitrarily combined without conflict.

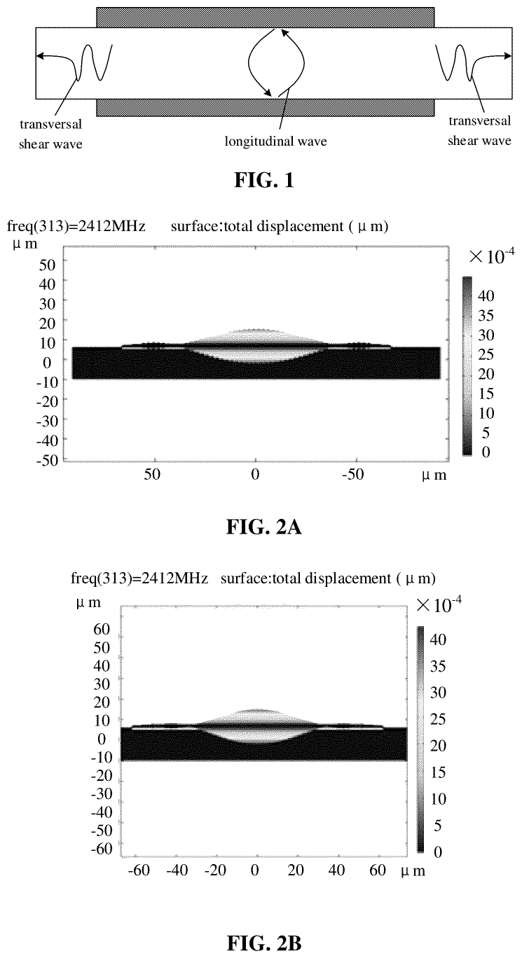

As illustrated in FIG. 1, in some implementations, in a case that electric energy is applied to an upper electrode and a lower electrode of the bulk acoustic wave resonator, the piezoelectric layer located between the upper electrode and the lower electrode generates acoustic waves due to the piezoelectric effect. In addition to longitudinal waves, transversal shear waves (can also be called lateral waves or shear waves) can also be generated in the piezoelectric layer. Existence of transversal shear waves may affect energy of main longitudinal waves. The transversal shear wave can lead to energy loss and deterioration of the Q value of the bulk acoustic wave resonator.

Research shows that grooves can be arranged at an edge of an active area of a piezoelectric layer of a bulk acoustic wave resonator to prevent transversal shear waves from propagating to an external region and to limit energy in the active area, thereby reducing the parasitic resonance and increasing the Q value.

In some embodiments, simulation tests on vibration modes of a bulk acoustic wave resonator are performed respectively for different cases in which there are the grooves and there is no grooves in the piezoelectric layer. FIG. 2A is a diagram of a simulation result of the vibration mode of the bulk acoustic wave resonator in a case that the piezoelectric layer has no grooves. FIG. 2B is a diagram of a simulation result of the vibration mode of the bulk acoustic wave resonator in a case that the piezoelectric layer has the grooves. It can be seen from FIG. 2A and FIG. 2B that lateral waves of the bulk acoustic wave resonator with the grooves have less interferences on longitudinal waves, and vibration is more concentrated in the middle of the active area. At the edge of the active area, the lateral waves are inhibited by the annular grooves, and the vibration amplitude is smaller.

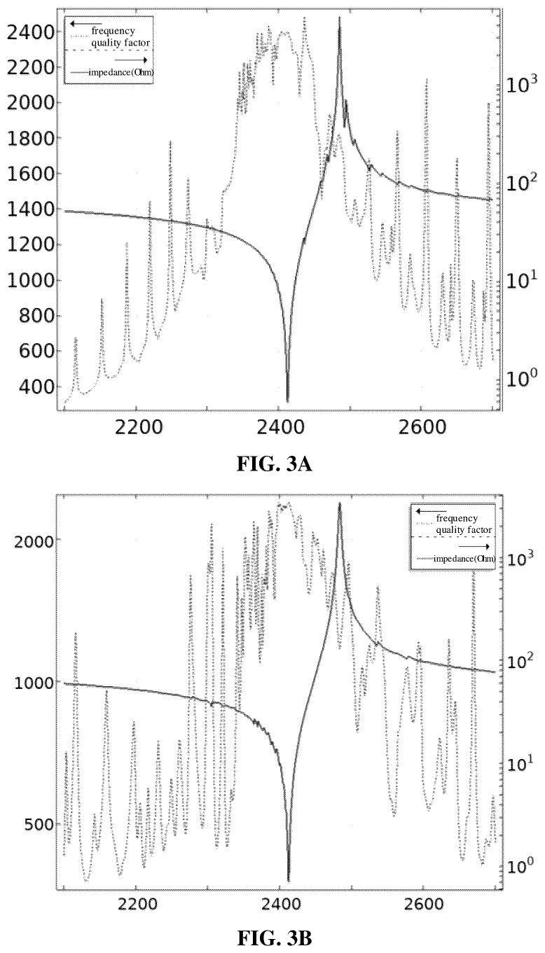

Tests on frequency quality factor and impedance of the bulk acoustic wave resonator are performed respectively for different cases in which there are the grooves and there is no groove in the piezoelectric layer. FIG. 3A is a diagram of a test result of the frequency quality factor and the impedance of the bulk acoustic wave resonator in the case that the piezoelectric layer has no grooves. FIG. 3B is a diagram of a test result of the frequency quality factor and the impedance of the bulk acoustic wave resonator in the case that the piezoelectric layer has the grooves. It can be seen from FIG. 3A and FIG. 3B that the Q value of the bulk acoustic wave resonator with the grooves is 2460, and that the Q value of the bulk acoustic wave resonator without the grooves is 2397. That is, the Q value of the bulk acoustic wave resonator with the grooves is greater.

A smith chart for the cases in which there are the grooves and there is no groove in the bulk acoustic wave resonator is observed. FIG. 4 is a diagram of the smith chart of the bulk acoustic wave resonator for different cases in which there are grooves and there is no groove in the piezoelectric layer. As illustrated in FIG. 4, the grooves can effectively reduce the parasitic resonance and transfer the parasitic resonance below series resonance point. That is, the design of adding grooves in the piezoelectric layer at the edge of the active area of the bulk acoustic wave resonator can attenuate lateral waves, so that the energy can be concentrated on longitudinal waves in the active area, thereby inhibiting transversal parasitic modes (i.e. inhibiting the parasitic resonance) and increasing the Q value.

Based on this, in various embodiments of the present disclosure, annular grooves are provided at the edge of the active area of the piezoelectric layer. The grooves can prevent transversal shear waves generated by the bulk acoustic wave resonator when stimulated by an electric field from propagating to the external region, limit energy to longitudinal waves in the active area and reduce energy leakage, thereby reducing the parasitic resonance and increasing the Q value.

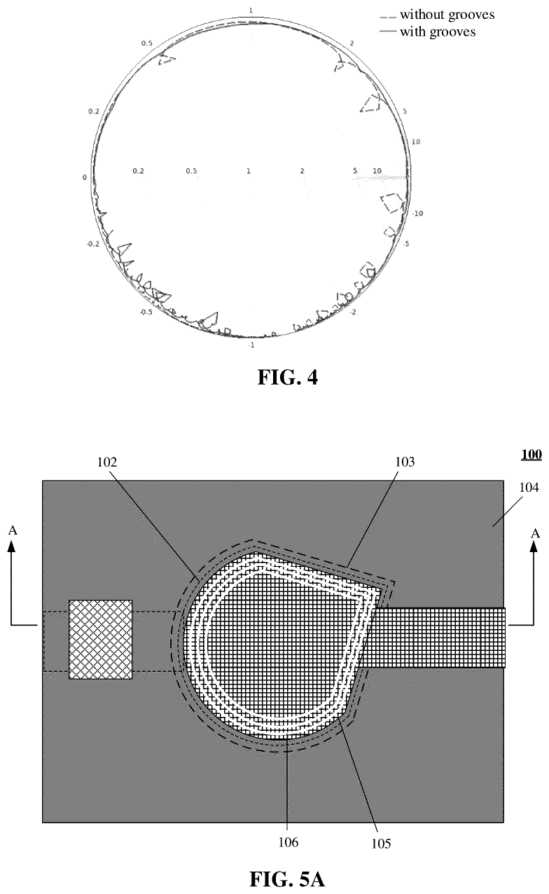

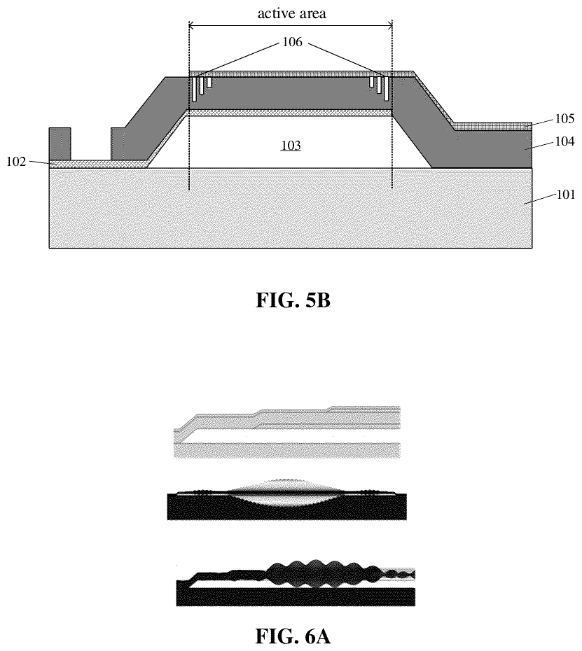

FIG. 5A is a top view diagram of a bulk acoustic wave resonance structure 100 according to an embodiment of the present disclosure. FIG. 5B is a cross-sectional diagram of the bulk acoustic wave resonance structure 100 in a direction A illustrated in FIG. 5A. As illustrated in FIG. 5B, the bulk acoustic wave resonance structure 100 includes a substrate 101 and includes a reflective structure 103, a first electrode layer 102, a piezoelectric layer 104 and a second electrode layer 105 stacked on the substrate in sequence. The piezoelectric layer 104 is provided with annular grooves 106, and the grooves 106 are located in an active area and close to an edge of the active area.

In practical application, material of the substrate 101 may include silicon (Si), germanium (Ge), and etc.

The first electrode layer 102 may be referred to as a lower electrode. Accordingly, the second electrode layer 105 may be referred to as an upper electrode. Electrical energy may be applied to the bulk acoustic wave resonator through the upper electrode and the lower electrode. Materials of the first electrode layer 102 and the second electrode layer 105 may be the same, and specifically may include aluminum (Al), molybdenum (Mo), ruthenium (Ru), iridium (Ir), platinum (Pt) or the like.

The piezoelectric layer 104 may be configured to generate vibration based on inverse piezoelectric characteristics so as to convert electrical signals loaded on the first electrode layer 102 and the second electrode layer 105 into acoustic wave signals, thereby achieving conversion of electrical energy to mechanical energy. In practical application, material of the piezoelectric layer 104 may include materials with piezoelectric characteristic, such as aluminum nitride, zinc oxide, lithium tantalate, and the like. The material of the piezoelectric layer 104 may be doped with piezoelectric materials such as scandium.

The reflective structure 103 is configured to reflect the acoustic wave signals. When the acoustic wave signals generated by the piezoelectric layer 104 propagates towards the reflective structure 103, the acoustic wave signals may be totally reflected at an interface where the first electrode layer 102 and the reflective structure 103 contact, so that the acoustic wave signals can be reflected back into the piezoelectric layer 104. Here the active area includes an area where the first electrode layer 102, the reflective structure 103, the piezoelectric layer 104 and the second electrode layer 105 overlap in a second direction (the active area as illustrated in FIG. 5B). The second direction is perpendicular to a surface of the substrate 101. The second direction can also be understood as a direction in which the reflective structure 103, the first electrode layer 102, the piezoelectric layer 104 and the second electrode layer 105 are stacked on the substrate 101.

The grooves 106 are disposed in the piezoelectric layer 104 and are disposed along the edge of the active area. That is, outer contours of the grooves 106 are similar to shapes of the upper electrode or the lower electrode. It should be noted that in practical application, the grooves 106 in the piezoelectric layer cannot be directly observed in the top view diagram illustrated in FIG. 5A. Here, in order to illustrate the grooves 106 more clearly, the grooves 106 are illustrated through the second electrode layer 105.

In the embodiment, the grooves 106 cannot be arranged outside the edge of the active area. Specifically, in order to determine an optimal position of the grooves 106, the grooves 106 are respectively arranged at different positions such as an inner edge of the active area, a first position outside the active area and a second position outside the active area for specific analysis. Here, the second position is farther from the active area than the first position.

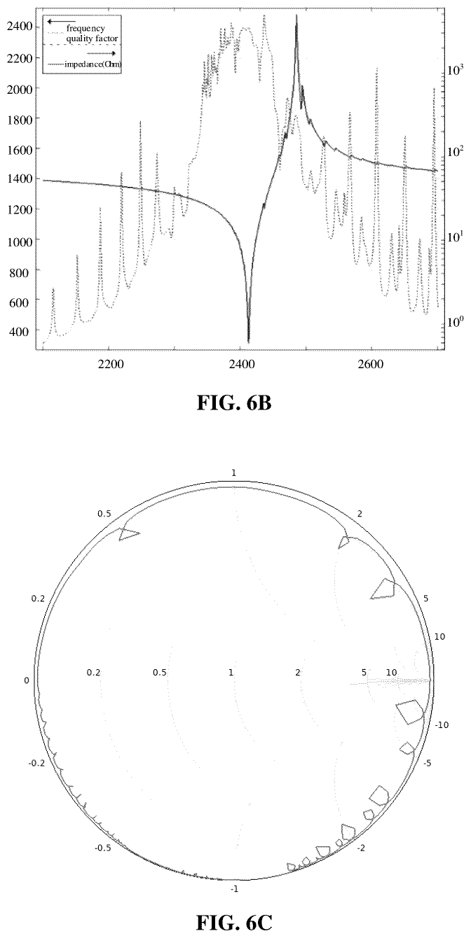

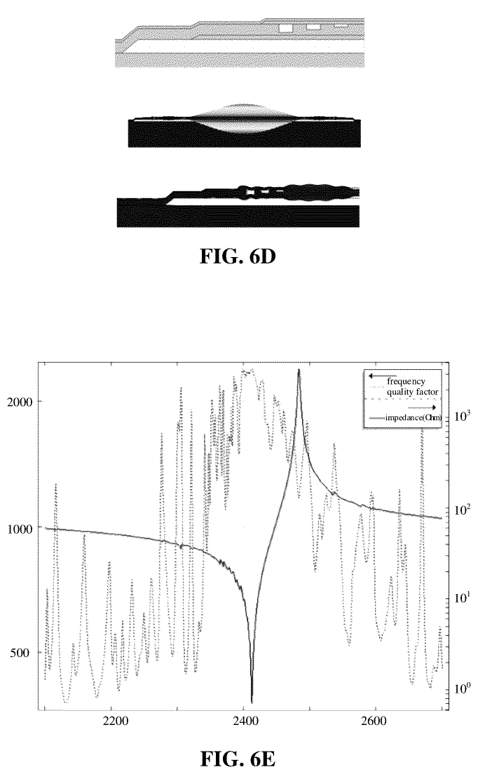

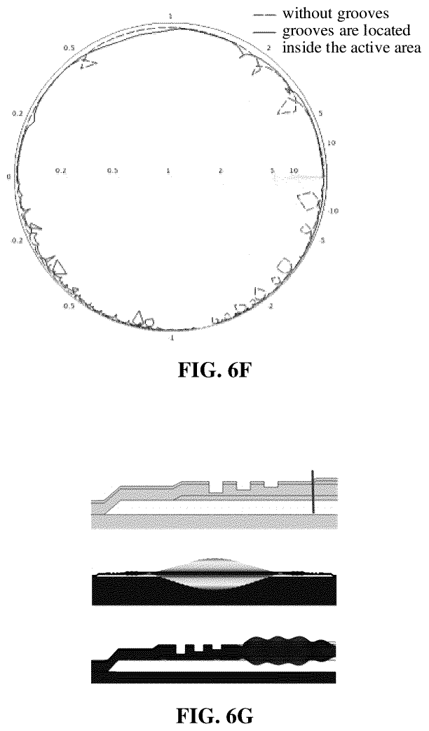

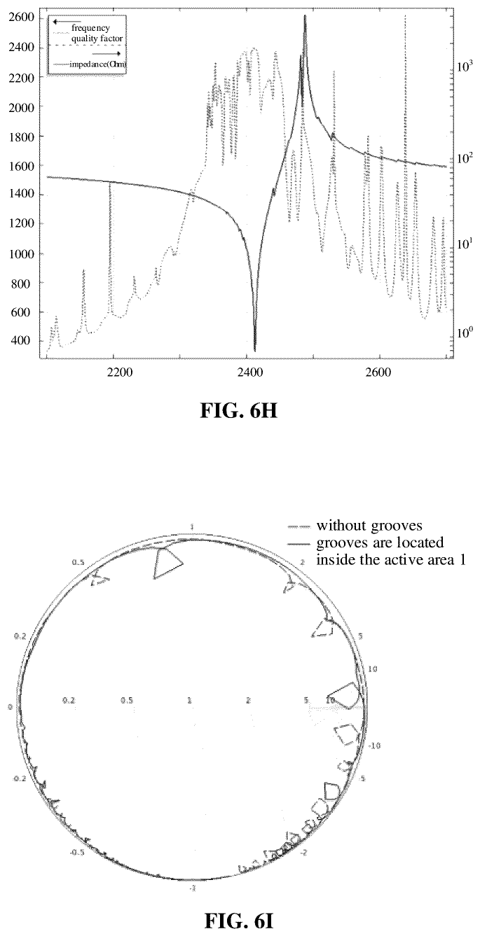

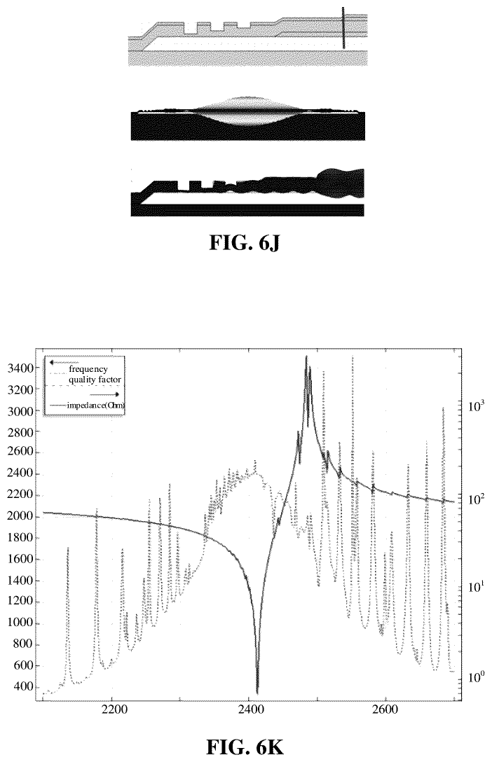

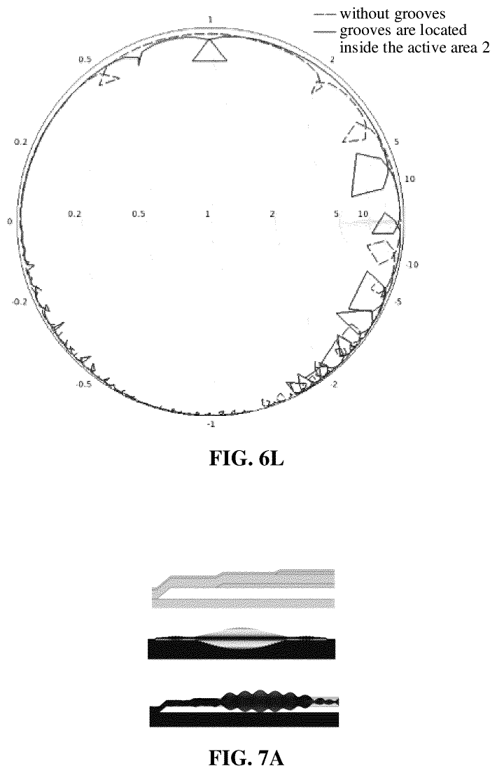

In practical application, FIGS. 6A to 6L illustrate influences on the lateral parasitic mode and the Q value when the grooves are arranged at different positions respectively in the embodiment of the present disclosure. FIGS. 6A, 6B and 6C illustrate test results of the bulk acoustic wave resonance structure when no grooves are arranged, FIGS. 6D, 6E and 6F illustrate test results of the bulk acoustic wave resonance structure when the grooves are arranged inside the active area, and FIGS. 6G, 6H and 6I illustrate test results of the bulk acoustic wave resonance structure when the grooves are arranged in the first position (corresponding to “a region outside the active area”. Specifically, the first position is outside the active area but inside the reflective structure) outside the active area, and FIGS. 6J, 6K and 6L illustrate test results of the bulk acoustic wave resonance structure when the grooves are arranged in the second position (corresponding to “another region outside the active area”. Specifically, the second position is outside the active area and outside the reflective structure) outside the active area. The first row of FIGS. 6A, 6D, 6G and 6J illustrate diagrams of grooves at different positions in the piezoelectric layer of the bulk acoustic wave resonator, the second row of FIGS. 6A, 6D, 6G and 6J illustrates diagrams of simulation test results of vibration mode of the bulk acoustic wave resonator, the third row of FIGS. 6A, 6D, 6G and 6J illustrates diagrams of simulation test results of local vibration mode of the bulk acoustic wave resonator, FIGS. 6B, 6E, 6H and 6K illustrate diagrams of test results of frequency quality factor and impedance of the bulk acoustic wave resonator, and FIGS. 6C, 6D, 6G and 6J illustrate diagrams of test results of smith chart of the bulk acoustic wave resonator. It can be seen from FIGS. 6A to 6L that compared with the bulk acoustic wave resonator without the grooves, arranging the grooves inside the active area of the bulk acoustic wave resonator may effectively reduce the parasitic resonance and increase the Q value. For the bulk acoustic wave resonator with the grooves arranged at the first position outside the active area, effect of inhibiting the parasitic resonance is insignificant but the Q value is increased. For the bulk acoustic wave resonator with the grooves arranged at the second position outside the active area, the parasitic resonance is enhanced instead of being inhibited. That is, in order to achieve the effects of reducing the parasitic resonance and increasing the Q value at the same time, the grooves 106 need to be arranged inside the active area. In practical application, a distance between outer edges of the grooves 106 and the edge of the active area can range from 0 μm to 10 μm, and is preferably 0 μm.

It can be understood that in the case that the grooves 106 are arranged near middle of the active area, the lateral waves generated in piezoelectric layer 104 near the edge of the active area, when propagating laterally, may not meet the grooves in the middle, thereby making the grooves 106 unable to function.

In some embodiments, an outer contour of the grooves 106 includes a closed shape, and the closed shape includes a curve and two or more straight lines.

In practical application, as illustrated in FIG. 5A, the outer contour of the grooves 106 may be slightly smaller than outer contour of the upper electrode so as to ensure that the energy can be limited to the active area. The outer contour can be understood with reference to FIG. 5A, and the outer contour is the outer edge shape of the grooves 106 as observed from a top view. It can be understood that when the outer contour of grooves 106 is a closed line segment with a uniform width, effect of limitation is better, and the energy can be better limited in the active area.

In some embodiments, the grooves 106 include multiple grooves arranged in sequence in a first direction. The first direction includes a direction from the edge of the active area to the middle of the active area. The number of the grooves is three. When the lateral waves propagate to the edge of active area along the film, most of the lateral waves would be reflected after encountering the air groove, and a small part the lateral waves would refract and transmit through the groove. After the lateral waves encounter multiple grooves continuously, most of the lateral waves are reflected.

Here, the multiple grooves 106 are all annular and arranged in sequence in the first direction. In practical application, as illustrated in FIG. 5A, perimeters of the rings in which the three grooves 106 are located are reduced in sequence in the first direction.

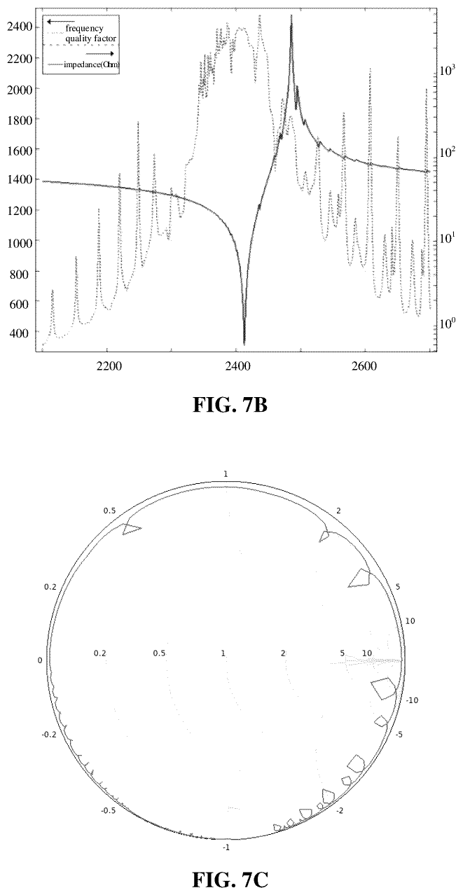

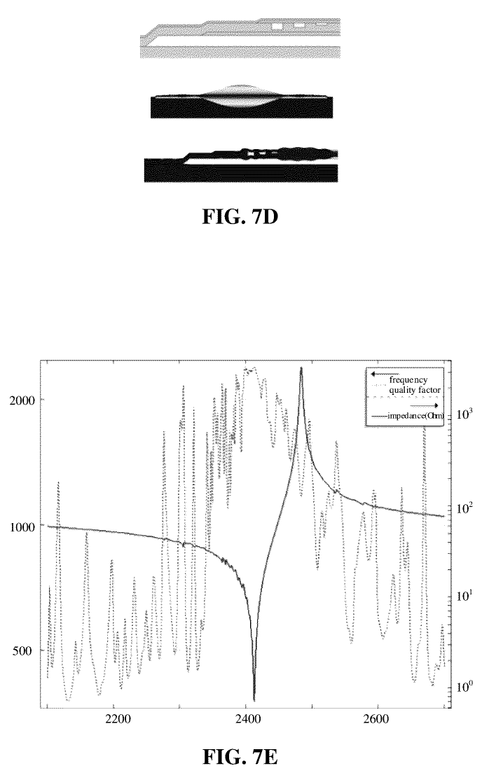

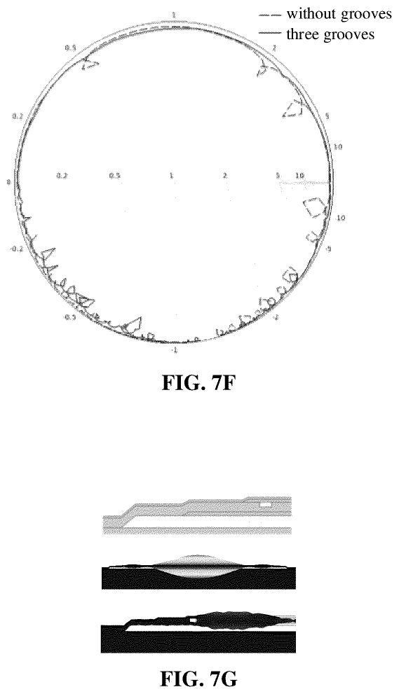

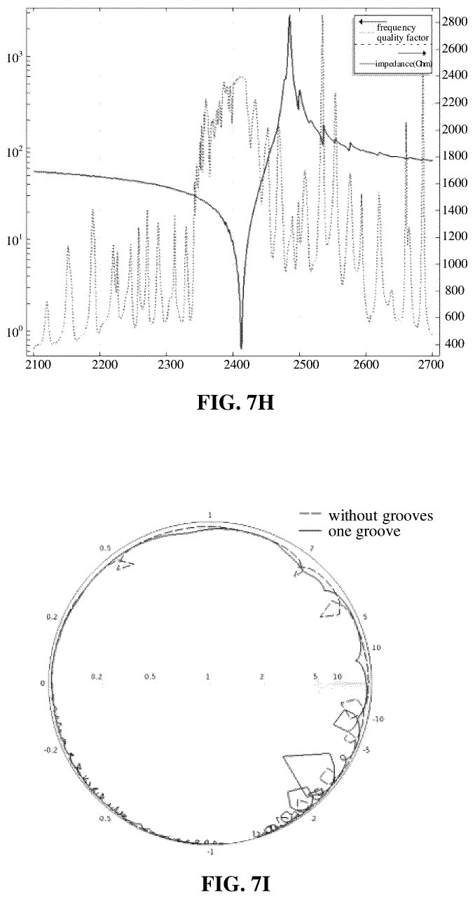

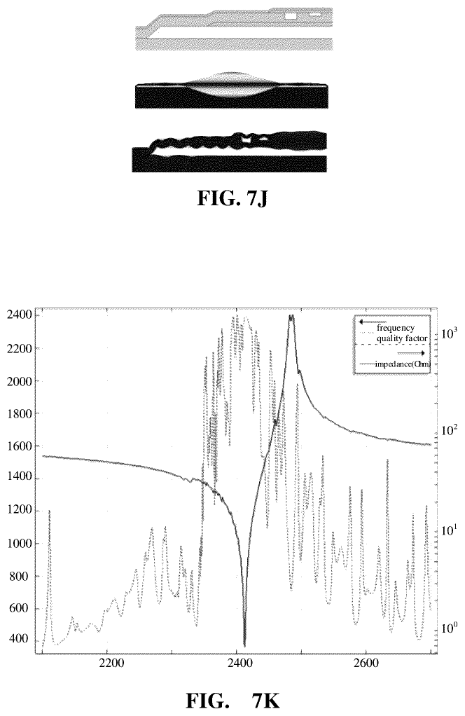

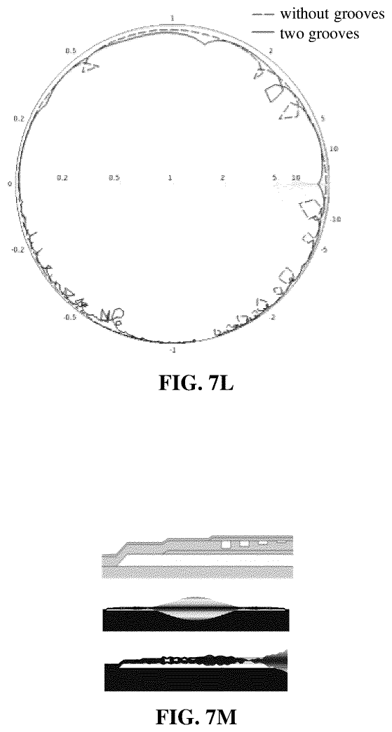

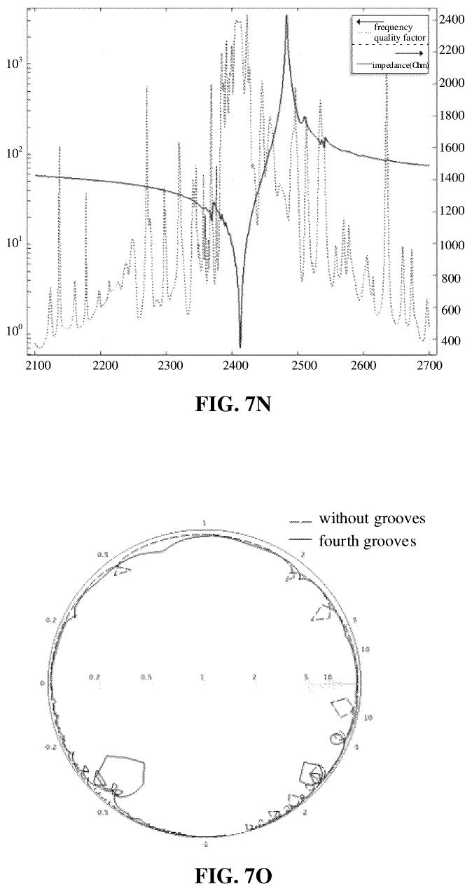

In practical application, FIGS. 7A to 7O illustrate influences on the lateral parasitic mode and the Q value when different numbers of grooves are provided in embodiments of the present disclosure. FIGS. 7A, 7B and 7C illustrate test results of the bulk acoustic wave resonance structure when the grooves are not arranged, FIGS. 7D, 7E and 7F illustrate test results of the bulk acoustic wave resonance structure when the number of the grooves is three, FIGS. 7G, 7H and 7I illustrate test results of the bulk acoustic wave resonance structure when the number of the grooves is one, FIGS. 7J, 7K and 7L illustrate test results of the bulk acoustic wave resonance structure when the number of the grooves is two, and FIGS. 7M, 7N and 7O illustrate test results of the bulk acoustic wave resonance structure when the number of the grooves is four. Test objects in FIGS. 7A to 7O are the same as test objects in FIGS. 6A to 6L. As can be seen from FIGS. 7A to 7O, compared with the bulk acoustic wave resonator without the grooves, arranging three grooves for the bulk acoustic wave resonator can effectively reduce the parasitic resonance and increase the Q value. When one groove or four grooves are arranged for the bulk acoustic wave resonator, the parasitic resonance can be inhibited, and the Q value can be increased, but some energy leaks to the second position outside the active area. When two grooves are arranged for the bulk acoustic wave resonator, the parasitic resonance can be inhibited, but the effect is slightly worse than that when three grooves are arranged for the bulk acoustic wave resonator. That is, when the number of grooves is set to three, the optimal effect of reducing the parasitic resonance and increasing the Q value can be achieved.

It should be noted that the bulk acoustic wave resonance structure illustrated in FIG. 5A and FIG. 5B are only an example of the present disclosure. In practical application, according to different shapes of the reflective structure 103, the bulk acoustic wave resonance structure can be specifically divided into a first-cavity-type Film Bulk Acoustic Wave Resonator (FBAR), a second-cavity-type FBAR, a Solid Mounted Resonator (SMR), and the like. However, the scheme provided in the present disclosure can be applied to the above mentioned different types of bulk acoustic wave resonance structures.

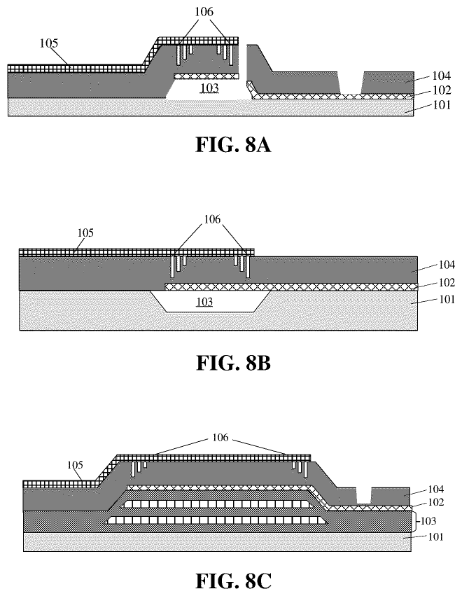

In some embodiments, when the bulk acoustic wave resonance structure 100 includes the first-cavity-type FBAR, the reflective structure 103 includes a first cavity formed between a protrusion of the first electrode layer 102 and the surface of the substrate 101, as illustrated in FIG. 8A.

In some embodiments, when the bulk acoustic wave resonance structure 100 includes the second-cavity-type FBAR, the reflective structure 103 includes a second cavity formed between a downward concavity from the surface of the substrate and the first electrode layer 102, as illustrated in FIG. 8B.

In some embodiments, when the bulk acoustic wave resonance structure 100 includes the SMR, the reflective structure 103 includes first dielectric layers and second dielectric layers that differ in acoustic impedances and are alternately stacked.

In some embodiments, the grooves 106 are provided with a filling material, and a difference between an acoustic impedance of the filling material and an acoustic impedance of a material of the piezoelectric layer 104 is greater than a preset value. Here the preset value can be adjusted according to actual situations. In practical application, the greater the difference between the acoustic impedance of the filling material in the grooves 106 and the acoustic impedance of the piezoelectric material, the higher the reflection efficiency. The grooves 106 can be filled with air, and an acoustic impedance of the air is much less than the acoustic impedance of the piezoelectric material. The grooves 106 can also be filled with an amorphous material. Exemplarily, the amorphous material includes silicon oxide (SiO₂). Grooves 106 filled with the amorphous material are illustrated in FIG. 9.

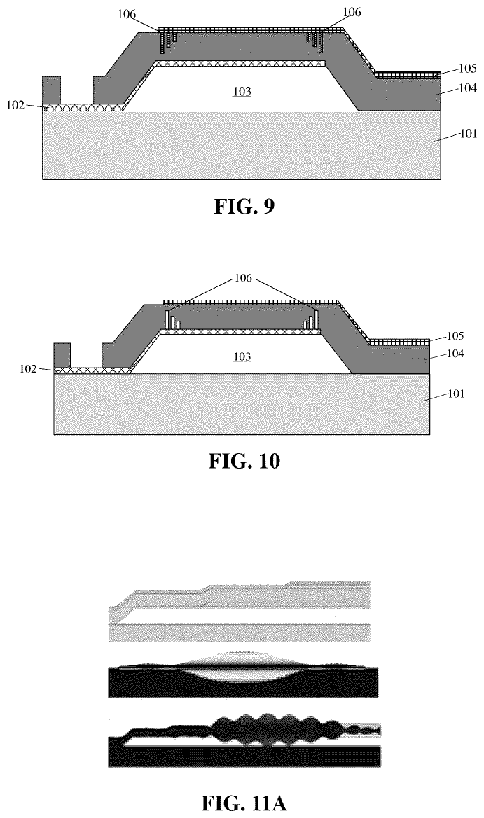

In some embodiments, openings of the grooves 106 face a top surface of the piezoelectric layer 104; or the openings of the grooves 106 face a bottom surface of the piezoelectric layer 104; or the grooves 106 are located in middle of the piezoelectric layer 104. In practical application, the case where the openings of the grooves 106 face the top surface of the piezoelectric layer 104 can refer to FIG. 5A, and the case where the openings of the grooves 106 face the bottom surface of the piezoelectric layer 104 can refer to FIG. 10. The grooves 106 are located in the middle of the piezoelectric layer 104 can be understood to be that the grooves 106 are actually cavities. The cavities are located in the middle of the piezoelectric layer 104 and have no opening orientation. It should be noted that when the openings of the grooves 106 face the bottom surface of the piezoelectric layer 104, or when the grooves 106 are located in the middle of the piezoelectric layer 104, the grooves 106 are provided with the filling material, which may include the amorphous material.

In practical application, when the groove(s) 106 include(s) multiple grooves, opening depths of the multiple grooves 106 meet different rules, which can also have different influences on eliminating the lateral parasitic mode and increasing the Q value.

In some embodiments, the opening depths of the multiple grooves 106 are smaller than a thickness of the piezoelectric layer 104, and the opening depths of the multiple grooves 106 are decreased progressively in the first direction, or increased progressively in the first direction, or partially the same, or all the same.

It should be understood that when the lateral waves generated in the piezoelectric layer transversely propagate to the edge of active area along the film (the propagation direction is opposite to the first direction), the lateral waves encounter the multiple grooves successively. When the opening depths of the encountered multiple grooves are increased progressively (the opening depths of the multiple grooves are decreased progressively in the first direction), the lateral waves are subjected to multiple changes from the propagation direction of lateral waves to a longitudinal propagation direction, and the changes are from weak to strong. Based on this, most lateral waves are reflected and converted into the longitudinal waves, which has an optimal effect of reducing the parasitic resonance and increasing the Q value.

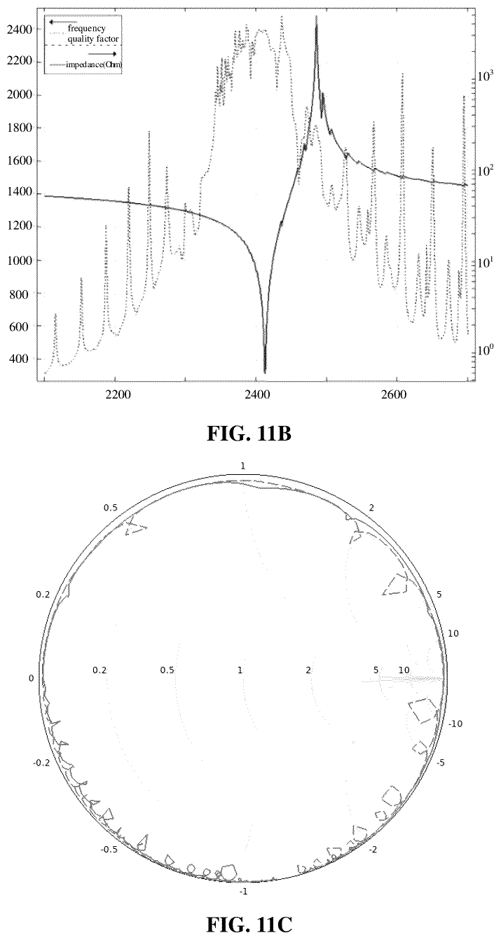

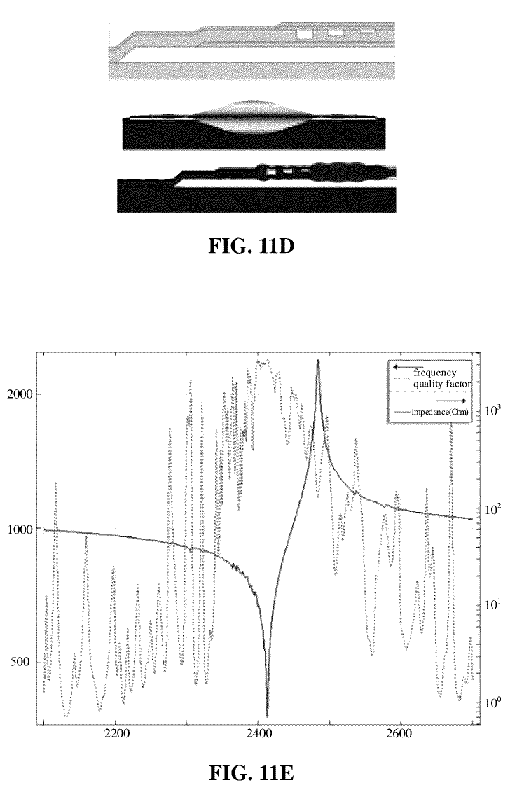

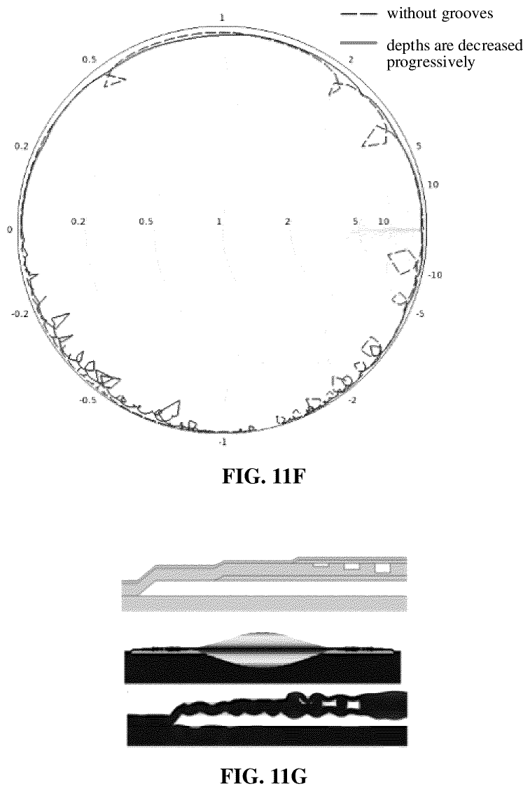

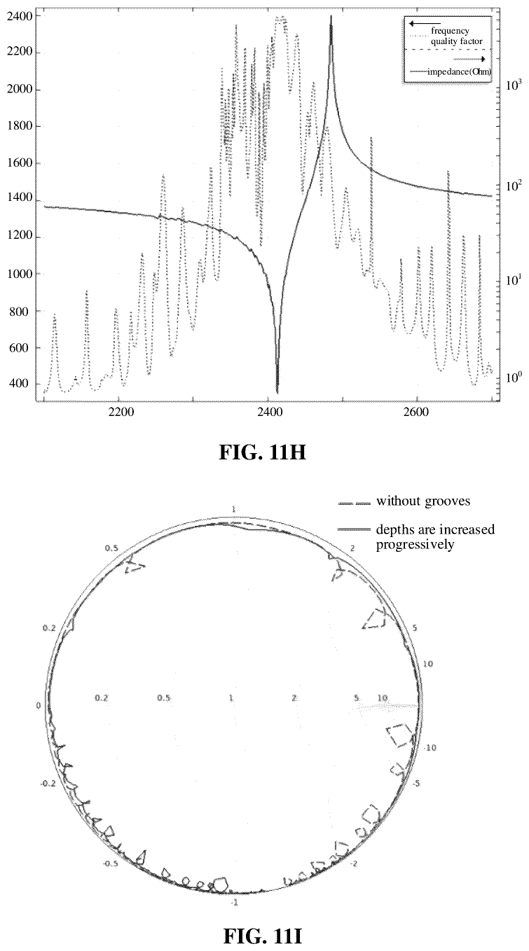

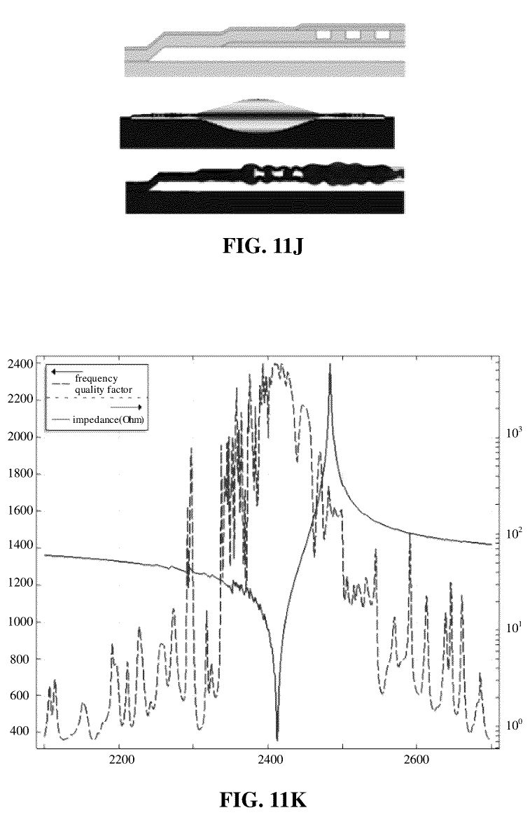

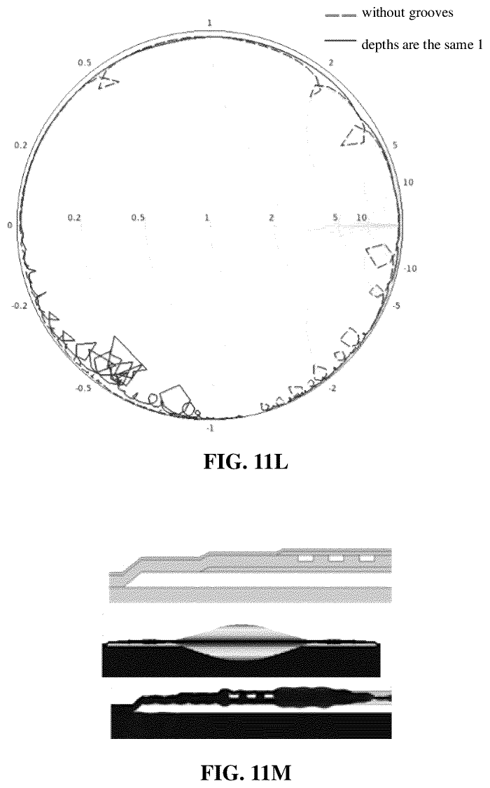

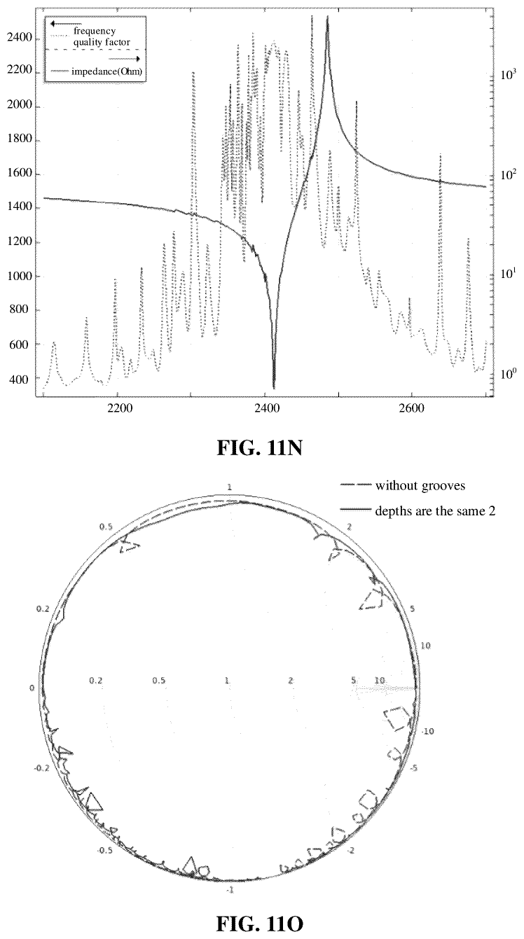

In practical application, in order to determine the optimal rule met by the opening depths of the multiple grooves 106, and the variation rules of the opening depths of the multiple grooves, different rules are set for specific analysis, which is illustrated in FIGS. 11A to 11O. FIGS. 11A, 11B and 11C illustrate test results of the bulk acoustic wave resonance structure when no grooves are arranged, FIGS. 11D, 11E and 11F illustrate test results of the bulk acoustic wave resonance structure when the opening depths of the multiple grooves are decreased progressively in the first direction, FIGS. 11G, 11H and 11I illustrate test results of the bulk acoustic wave resonance structure when the opening depths of the multiple grooves are increased progressively in the first direction, FIGS. 11J, 11K and 11L illustrate test results of the bulk acoustic wave resonance structure when the opening depths of the multiple grooves are all the same and are all a first depth, FIGS. 11M, 11N and 11O illustrate test results of the bulk acoustic wave resonance structure when the opening depths of the multiple grooves are all the same and are all a second depth (the first depth is greater than the second depth). Test objects in FIGS. 11A to 11O are the same as test objects in FIGS. 6A to 6L. As can be seen from FIGS. 11A to 11O, compared with the bulk acoustic wave resonator without the grooves, arranging the opening depths of the multiple grooves decreased progressively in the first direction for the bulk acoustic wave resonator can effectively reduce the parasitic resonance, transfer the parasitic resonance to be below the series resonance point, and increase the Q value. When the opening depths of the multiple grooves of the bulk acoustic wave resonator are increased progressively in the first direction, the parasitic resonance can be reduced and the Q value can be slightly increased. When the opening depths of the multiple grooves of the bulk acoustic wave resonator are all the same and are all the first depth (e.g. 0.6 μm), the parasitic resonance can be effectively reduced and transferred to be below the series resonance point, but the transferred parasitic resonance is greater than the parasitic resonance of the resonator with grooves of different depths. At the same time, the Q value can be increased. When the opening depths of the multiple grooves of the bulk acoustic wave resonator are all the same and are all the second depth (e.g. 0.4 μm), the parasitic resonance can be reduced, but the effect is not as good as the effect of the resonator with the first depth. That is, when the opening depths of the multiple grooves are decreased progressively in the first direction, the optimal effect of reducing the parasitic resonance and increasing the Q can be achieved.

Based on this, in some embodiments, the opening depths of the multiple grooves 106 are decreased progressively in the first direction. In some embodiments, the number of the grooves 106 is N, and an i-th groove of the N grooves in the first direction has an opening depth of (N−i+1)×H/(N+1). N is a positive integer greater than 1. i is a positive integer. i is greater than or equal to 1 and is less than or equal to N. H is the thickness of the piezoelectric layer.

In other implementations, opening depths of part of the multiple grooves 106 are the same (e.g. opening depths of any two or more grooves are the same) and are different from opening depths of other grooves. That is, the opening depths of the multiple grooves may not be decreased or increased progressively in the first direction. For example, when there are three grooves, the opening depths of two grooves may be the same, and are different from the opening depth of a third groove.

In practical application, N can range from 1 to 4. When the number of the grooves is three, opening depths of the three grooves can be a multiple of a quarter of the thickness of the piezoelectric layer. Specifically, the opening depths of the three grooves can be 3/4H, 2/4H and 1/4H in sequence. When the opening depths of the grooves are the multiple of a quarter of the thickness of the piezoelectric layer, the propagation direction of the refracted lateral waves would be changed to be longitudinal, and thus the lateral waves would be changed into longitudinal waves, which are just needed.

In some embodiments, the opening depths of the multiple grooves 106 are increased progressively in the first direction. The number of the grooves is N, and an i-th groove of the N grooves in the first direction has an opening depth of i×H/(N+1). N is a positive integer greater than 1. i is a positive integer. i is greater than or equal to 1 and is less than or equal to N. H is the thickness of the piezoelectric layer.

In practical application, when the number of the grooves is three, the opening depths of the three grooves can be the multiple of a quarter of the thickness of the piezoelectric layer. Specifically, the opening depths of the three grooves can be 1/4H, 2/4H and 3/4H in sequence.

In some embodiments, the opening depths of multiple grooves 106 are the same. The opening depths of the multiple grooves range from 1/2H to H. H is the thickness of the piezoelectric layer.

In practical application, when the opening depths of multiple grooves are the same, different opening depths can be set, and an optimal range of the opening depths can be determined through specific analysis according to the corresponding test results.

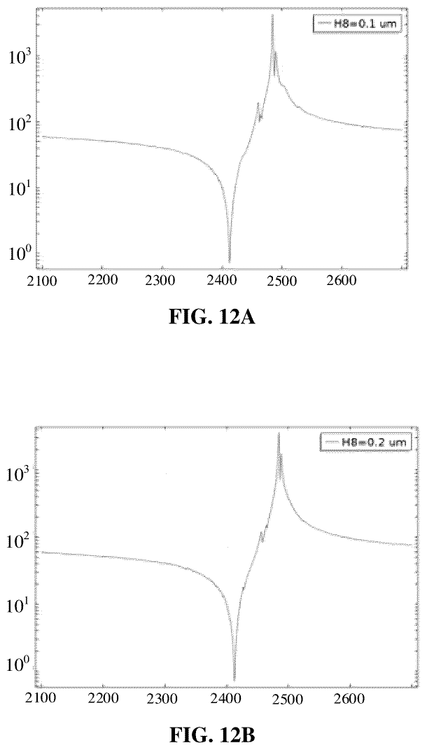

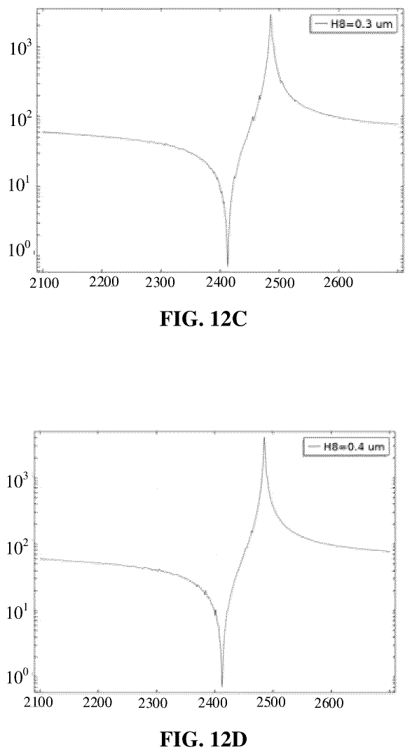

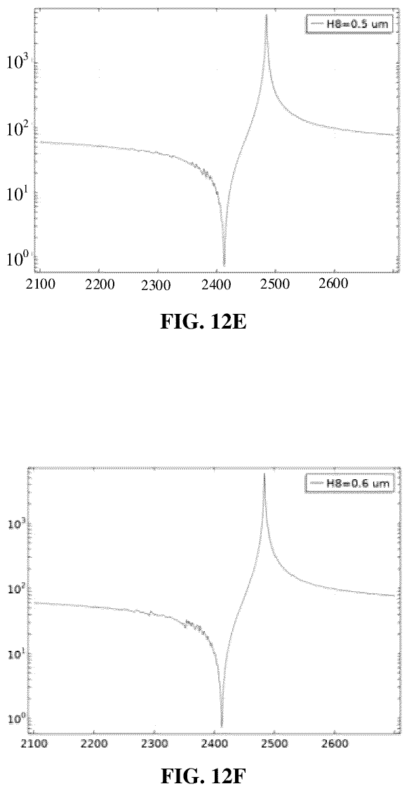

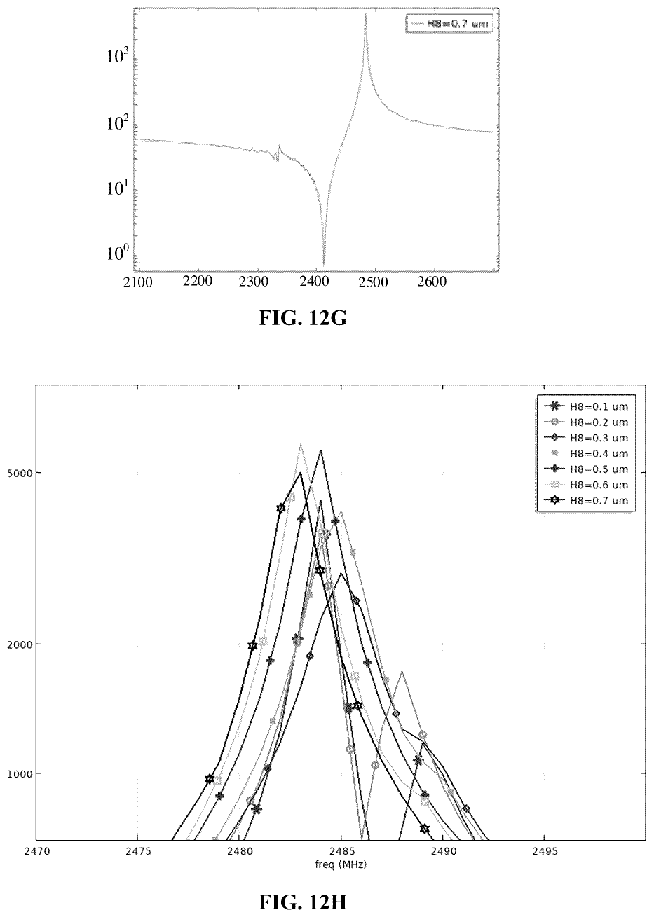

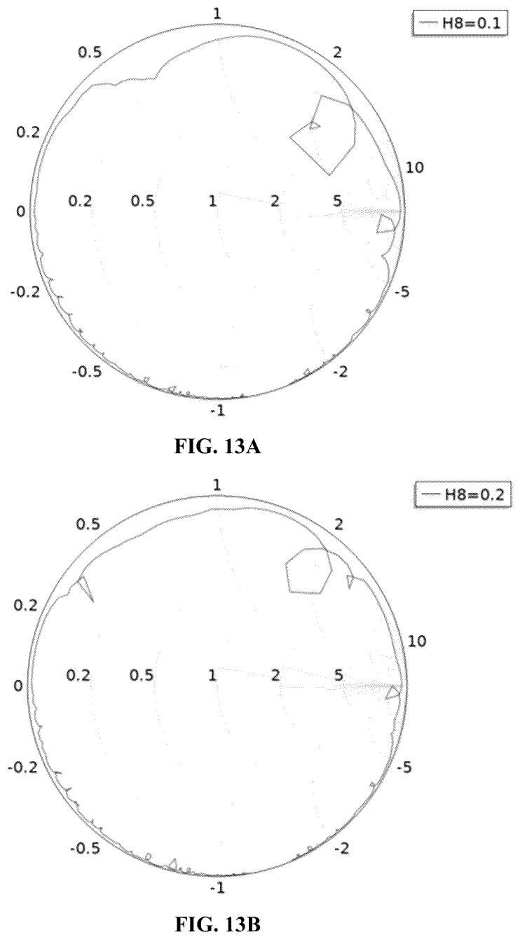

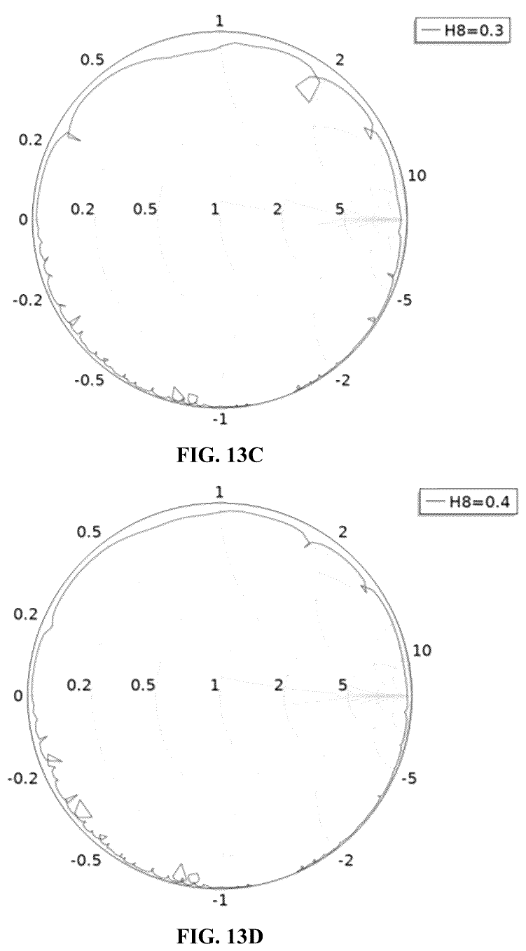

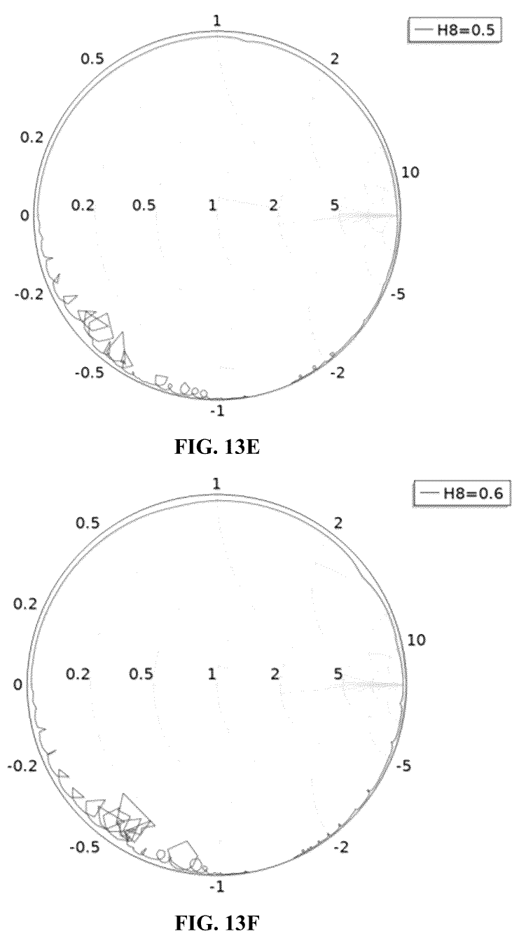

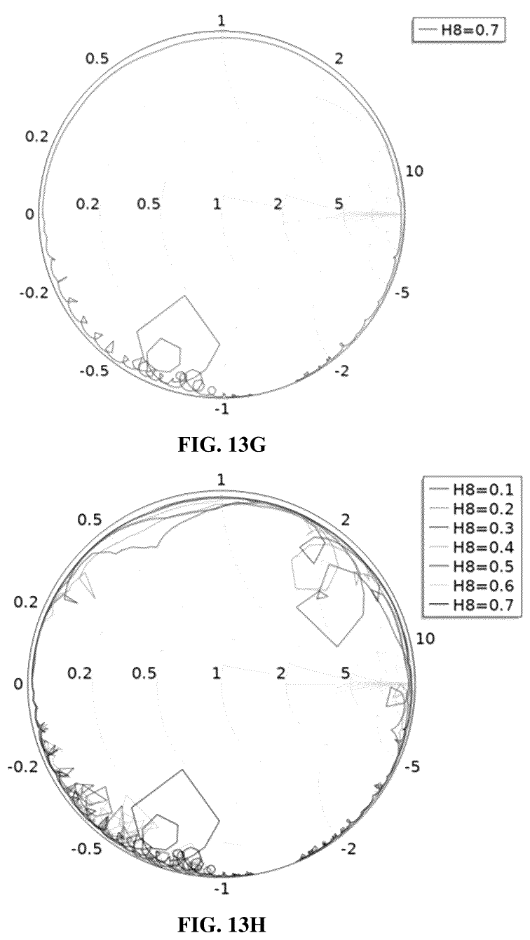

FIGS. 12A to 12H are diagrams of test results of relationship between impedance and frequency of the bulk acoustic wave resonator for different opening depths. FIGS. 13A to 13H are diagrams of test results of smith charts of the bulk acoustic wave resonator for different opening depths. It should be noted that H8 in FIGS. 12A to 12H and FIGS. 13A to 13H denotes the opening depth of the grooves, and the unit of the opening depth is μm. Meanwhile, the test in FIGS. 12A to 12H and FIGS. 13A to 13H is performed on the premise that the thickness of the piezoelectric layer is 0.8 μm. As can be seen from FIGS. 12A to 12H and FIGS. 13A to 13H, although the resonator with grooves of 0.1 μm has a high Q value, the smith charts are not smooth, and there is a large disturbance in the serial-parallel resonance point. With increase of the depths of the grooves, the parasitic resonance in the serial-parallel resonance point gradually disappears, and the parasitic resonances below the series resonance point gradually increase. When the depths of the grooves are greater than 0.6 μm, the parasitic resonances would gradually concentrate, and a larger parasitic resonance would be formed below the series resonance point.

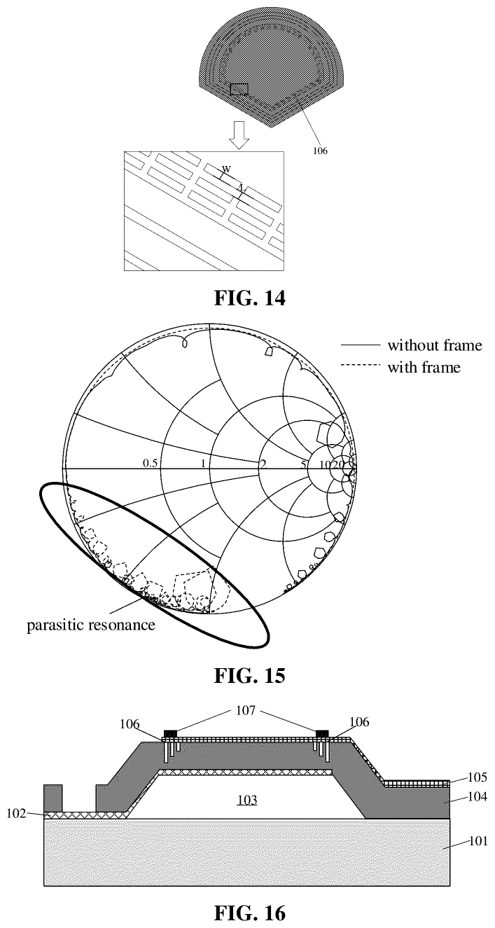

In some embodiments, the groove(s) 106 may include multiple sub grooves, and the multiple sub grooves form an annular shape together, as illustrated in FIG. 14. That is, a groove may not be a complete groove, but is composed of multiple sub grooves. In some embodiments, opening depths of the multiple sub grooves are the same. Cross-section of each of the multiple sub grooves is of a rectangular shape, a circular shape or an oval shape. The cross section here refers to cross-section in a horizontal direction. A shape of the cross-section of the sub groove is a top view shape after forming a horizontal cross-section of the piezoelectric layer.

As mentioned above, when the opening depths of the grooves are the multiple of a quarter of the thickness of the piezoelectric layer, the propagation direction of the refracted lateral waves would be changed to be longitudinal, and the lateral waves would be changed into longitudinal waves, which are just needed. At the same time, if spacings between the sub grooves and the opening depths of the sub grooves are not designed properly, lateral waves would be reflected back and forth between adjacent grooves to form standing waves, and a high-order resonance of the standing waves may be located near the serial resonance point of the longitudinal waves, thereby affecting the performance of resonator. Based on this, in order to destroy interference of the lateral waves, the spacings between the sub grooves and the opening depths of the sub grooves cannot be an integer multiple of a half wavelength of a higher harmonic of lateral waves generated in the piezoelectric layer. Here, the opening depths of the sub grooves refer to sizes of the openings of the sub grooves in the first direction, and more specifically, reference can be made to W illustrated in FIG. 14. The spacings between the sub grooves refer to sizes of the spacings between the sub grooves in the first direction, and more specifically, reference can be made to L illustrated in FIG. 14.

Based on this, in some embodiments, both the opening widths of the sub grooves and the spacings between adjacent sub grooves are different from an integer multiple of a half wavelength of a higher harmonic of the lateral waves generated in the piezoelectric layer.

In some embodiments, the opening widths of the sub grooves range from 0.05 μm to 10 μm, and the spacings between adjacent sub grooves range from 0.05 μm to 10 μm.

Exemplarily, as illustrated in FIG. 14, the cross-section of the sub grooves is of a rectangular shape. The opening width W of the sub grooves is 1 μm, and the spacing L between the sub grooves is 1 μm. The length of the sub grooves (i.e. the size of the openings of the sub grooves in a direction perpendicular to the first direction) is 5 μm.

In some embodiments, a frame may be formed above the upper electrode layer. FIG. 15 is a diagram of a smith chart of the bulk acoustic wave resonator with or without a frame above the upper electrode layer. As illustrated in FIG. 15, the frame can inhibit the lateral waves in the active area, so that the parasitic resonance in the serial-parallel resonance point of the bulk acoustic wave resonator is reduced, but the parasitic resonance below the series resonance point is significantly increased. Comparing FIG. 4 with FIG. 15, the bulk acoustic wave resonator with the grooves has a much smaller parasitic resonance below the series resonance point than the bulk acoustic wave resonator with the frame, which is almost negligible.

In view of this, in the embodiments of the present disclosure, the frame 107 can be formed above the second electrode layer 105. Meanwhile, the annular grooves 106 can be formed in the piezoelectric layer 104, so that the parasitic resonance of the bulk acoustic wave resonator can be reduced and the Q value can be increased by using the frame 107, and the parasitic resonance can be significantly reduced by using the grooves 106.

In some embodiments, at least one of the first electrode layer, the piezoelectric layer or the second electrode layer is provided with the frame 107 formed by a protruding block or a grooved region, and the number of the protruding block(s) or the grooved region(s) is at least one. The frame 107 has an annular three-dimensional structure. The frame 107 is located in the active area and close to the edge of the active area.

In practical application, as illustrated in FIG. 16, the frame 107 is disposed on a surface of the second electrode layer 105 and is disposed along the edge of the active area. That is, outer contour of the frame 107 is similar to the shapes of the upper electrode or the lower electrode. In some embodiments, the frame 107 may be formed by a curve and two or more straight lines. In practical application, the outer contour of the frame 107 may be slightly smaller than the outer contour of the upper electrode so as to ensure that the energy can be limited in the active area. Here, the frame 107 may have the annular three-dimensional structure, which means that the frame 107 has a certain width and thickness. In other embodiments, the outer contour of the frame 107 is a closed line segment with a uniform width.

In some embodiments, the material of the frame 107 can be the same as or different from the materials of the first electrode layer 102 and the second electrode layer 105. More specifically, in some embodiments, the material of the frame 107 may include aluminum, molybdenum, ruthenium, iridium, platinum, or the like, and the material of the frame 107 may include aluminum. When the material of the frame 107 is the same as the material of the second electrode layer 105, the frame 107 may be formed together with the second electrode layer 105 or may be formed separately after the second electrode layer 105 is formed.

In the bulk acoustic wave resonator with the grooves 106 and the frame 107, the rules met by position(s) of the groove(s) 106, the number of the groove(s) 106, and when there are multiple grooves, the opening depths of the multiple grooves 106 are analyzed. Specifically:

In practical application, when the frame 107 is provided, in order to determine the optimal position of the groove(s) 106, the groove(s) 106 is/are arranged at different positions, for example, inside the active area, a first position outside the active area and a second position outside the active area, to carry out specific analysis. The second position is farther from the active area than the first position.

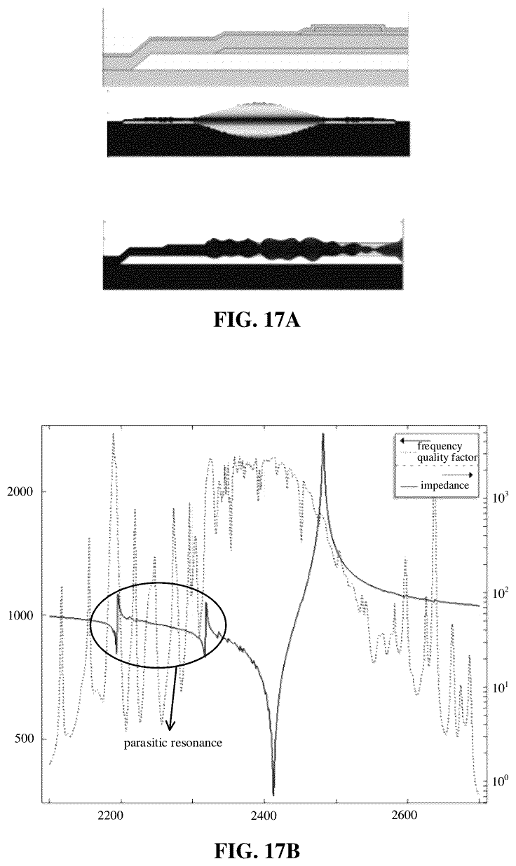

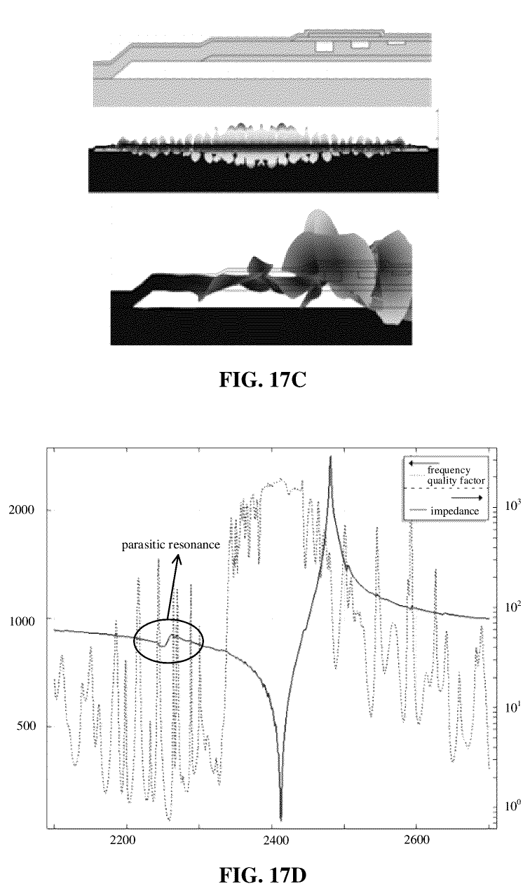

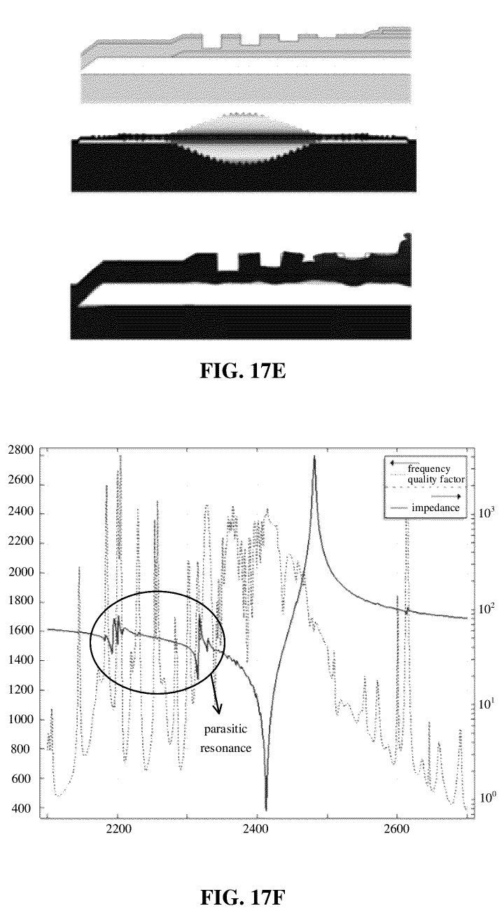

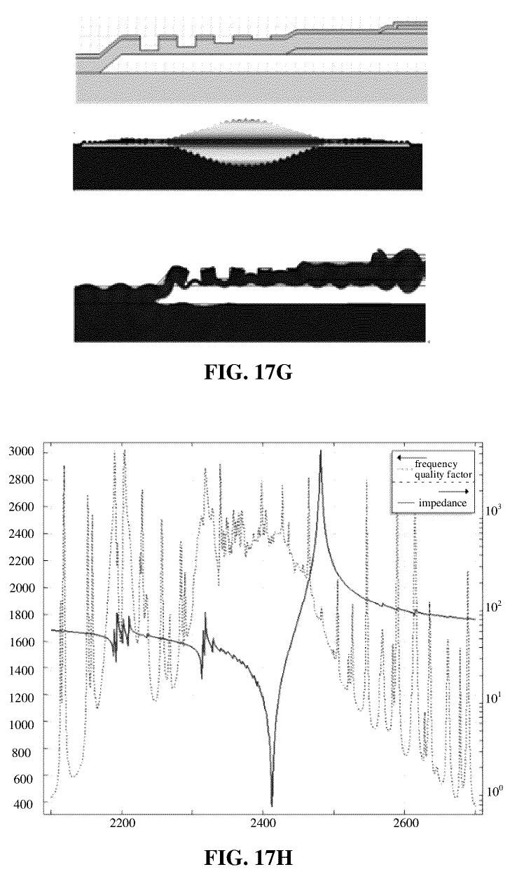

In practical application, FIGS. 17A to 17H illustrates influences on the lateral parasitic mode and the Q value when the groove(s) is/are arranged at different positions according to the embodiments of the present disclosure. Description of FIGS. 17A to 17H can refer to FIGS. 6A to 6L. As can be seen from FIGS. 17A to 17H, compared with the bulk acoustic wave resonator without grooves, arranging the groove(s) in the active area of the bulk acoustic wave resonator can reduce the parasitic resonance and increase the Q value. For the bulk acoustic wave resonator with the groove(s) arranged at the first position outside the active area, effect of inhibiting the parasitic resonance is not obvious and the Q value is not increased. For the bulk acoustic wave resonator with the groove(s) arranged at the second position outside the active area, part of the energy may leak to the second position outside the active area, so that the piezoelectric layer at the second position outside the active area would made vibrate and displaced. That is, when the frame 107 is provided, in order to achieve the effects of reducing the parasitic resonance and increasing the Q value at the same time, the groove(s) 106 should also be arranged inside the active area.

In a practical application, when the frame 107 is provided, in order to determine the optimal number of the grooves 106, specific analyses are made by arranging different numbers of the groove(s) 106.

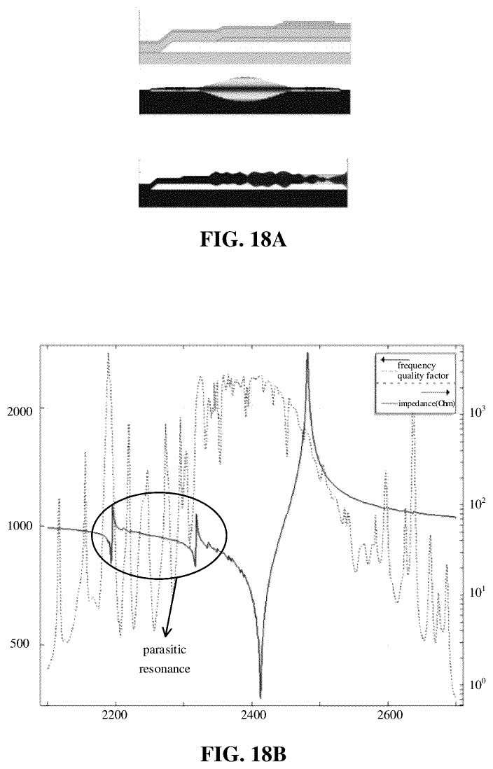

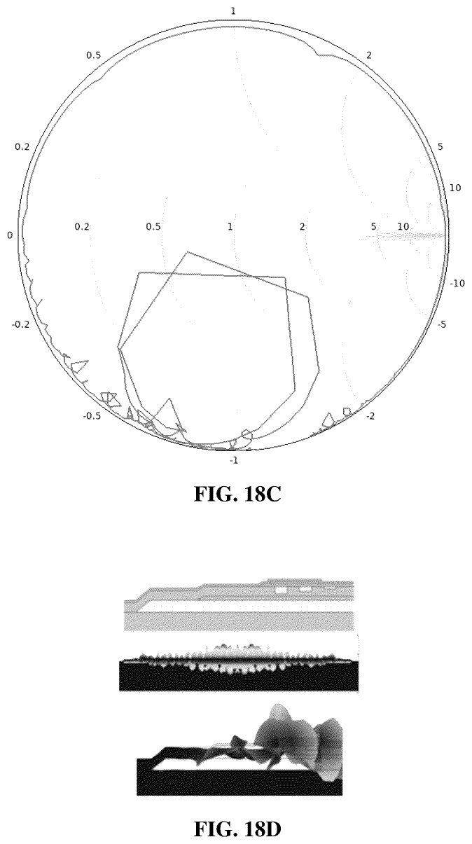

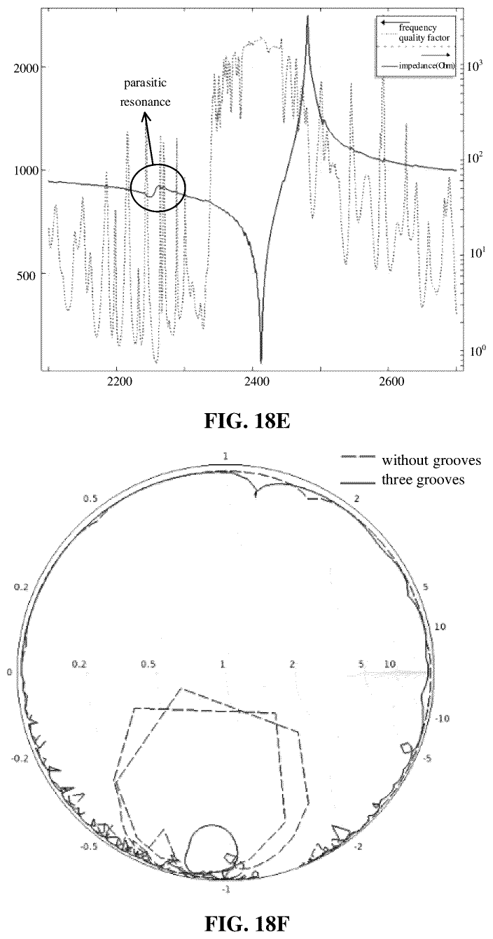

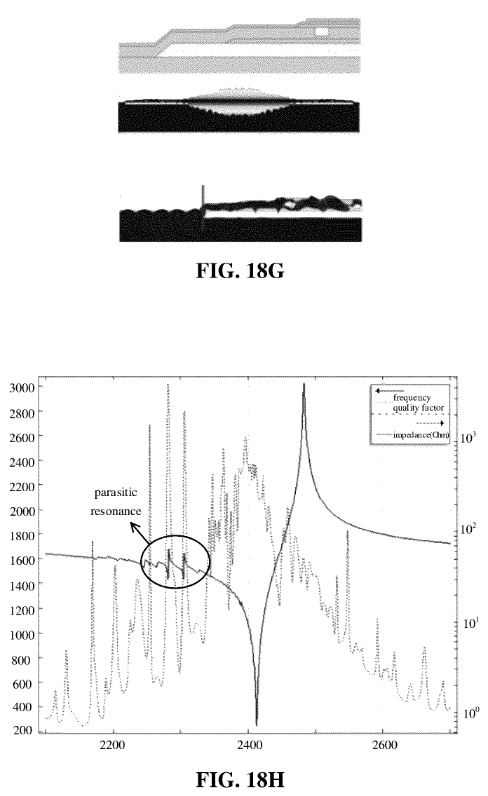

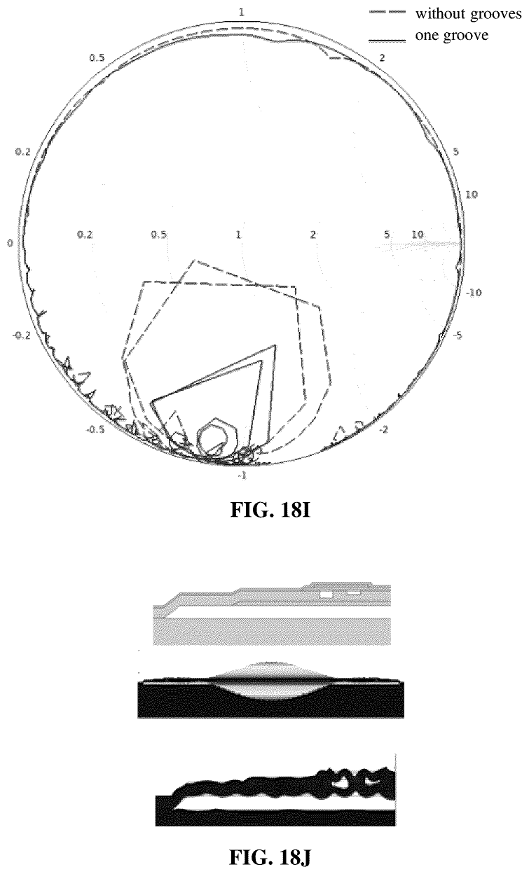

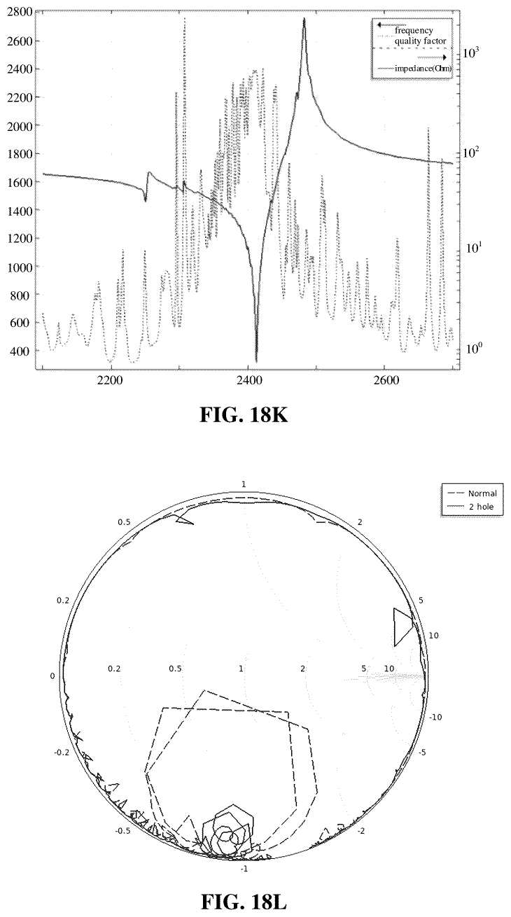

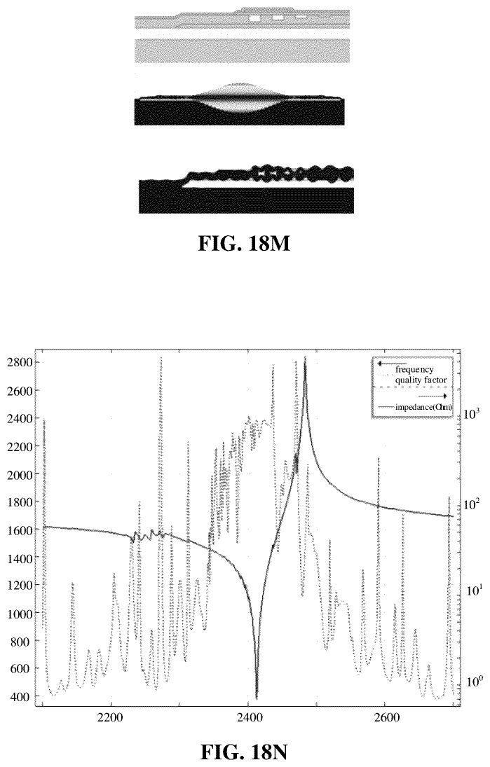

FIGS. 18A to 18O illustrates influences on the lateral parasitic mode and the Q value when different numbers of the groove(s) are provided according to an embodiment of the present disclosure. Description of FIGS. 18A to 18O can refer to FIGS. 7A to 7O. As can be seen from FIGS. 18A to 18O, compared with the bulk acoustic wave resonator without grooves, arranging three grooves for the bulk acoustic wave resonator can reduce the parasitic resonance, and the Q value can be increased at the same time. When one groove or four grooves are arranged for the bulk acoustic wave resonator, the parasitic resonance can be inhibited, and the Q value can be increased, but some energy can leak to a non-cavity area. When two grooves are arranged for the bulk acoustic wave resonator, the parasitic resonance can be inhibited, but the effect is slightly worse than that when three grooves are arranged. That is, when the frame 107 is provided and the number of the grooves 106 is three, the optimal effect of reducing the parasitic resonance and increasing the Q value can be achieved.

In practical application, when the frame 107 is provided, in order to determine the optimal rule met by the opening depths of the multiple grooves 106, different rules are set for specific analysis.

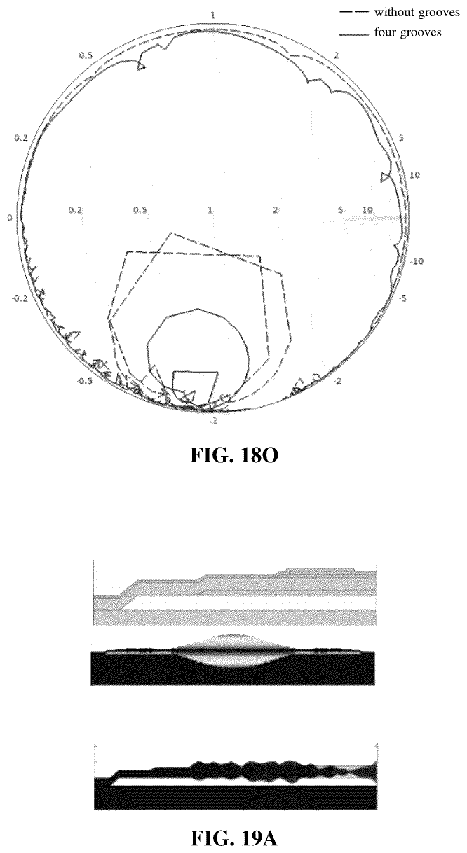

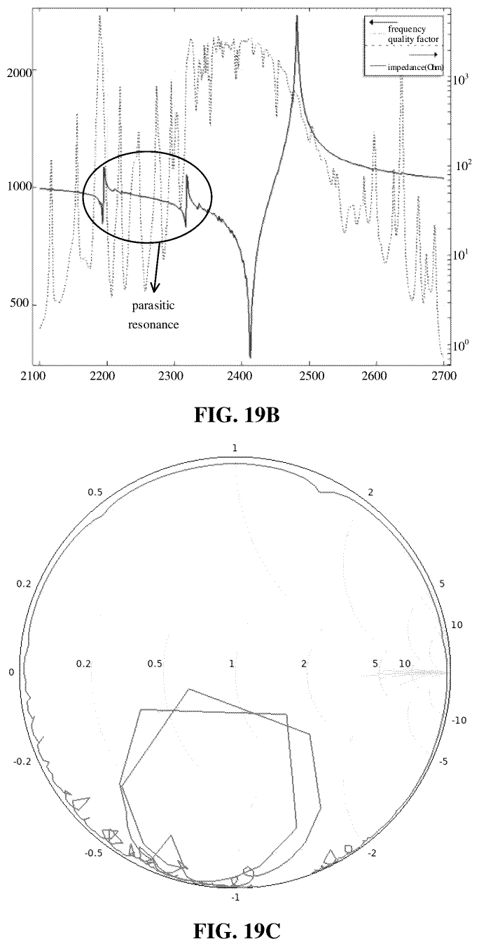

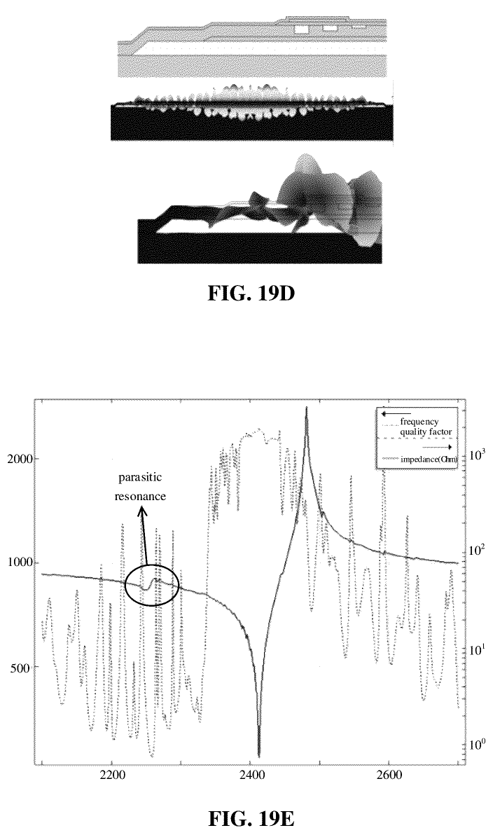

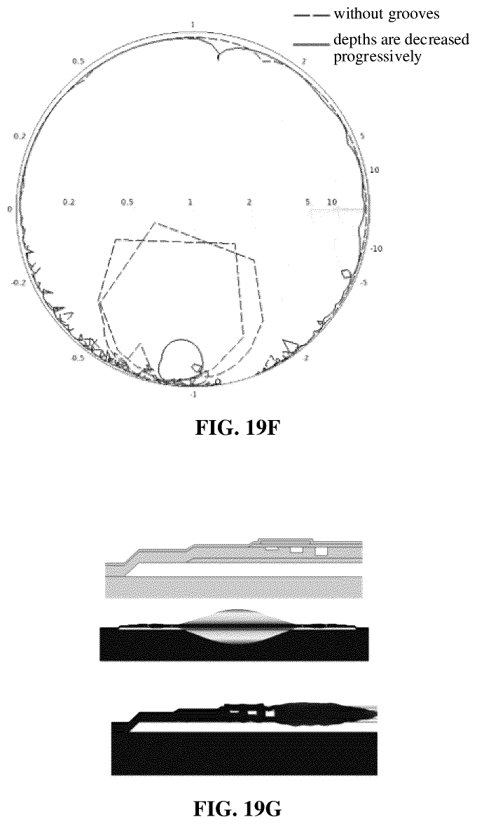

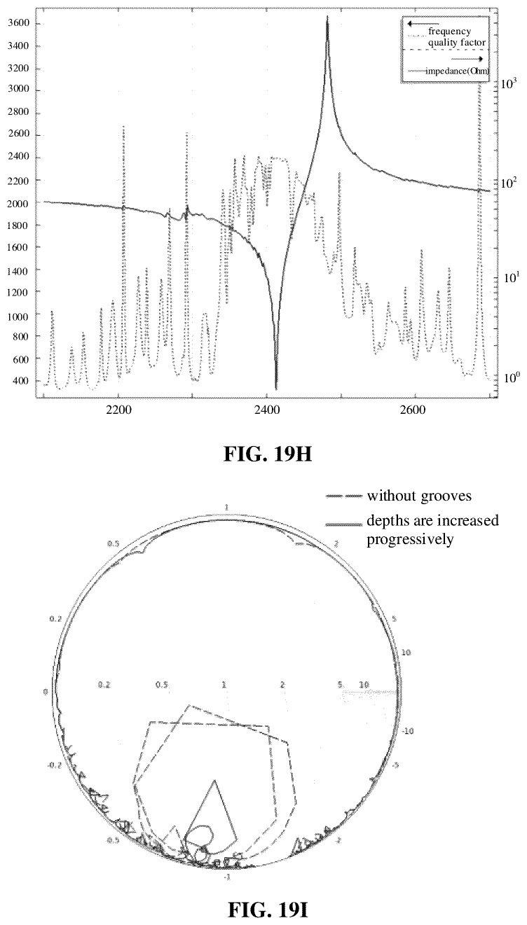

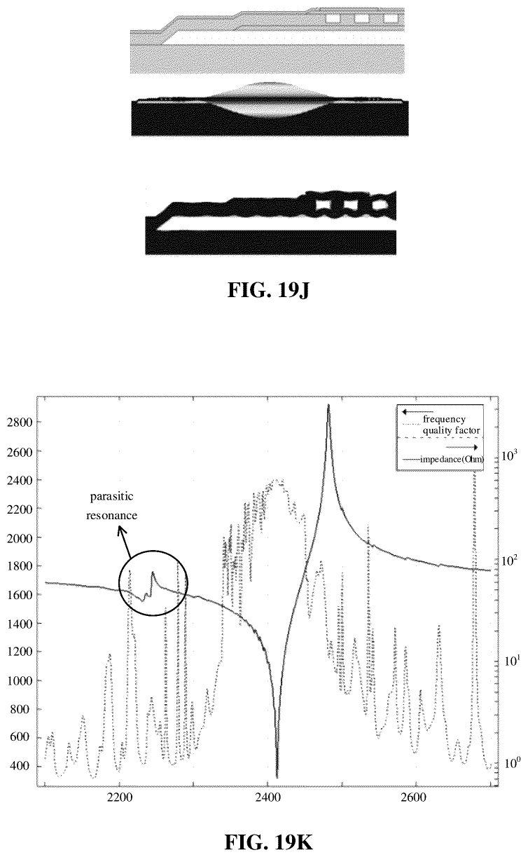

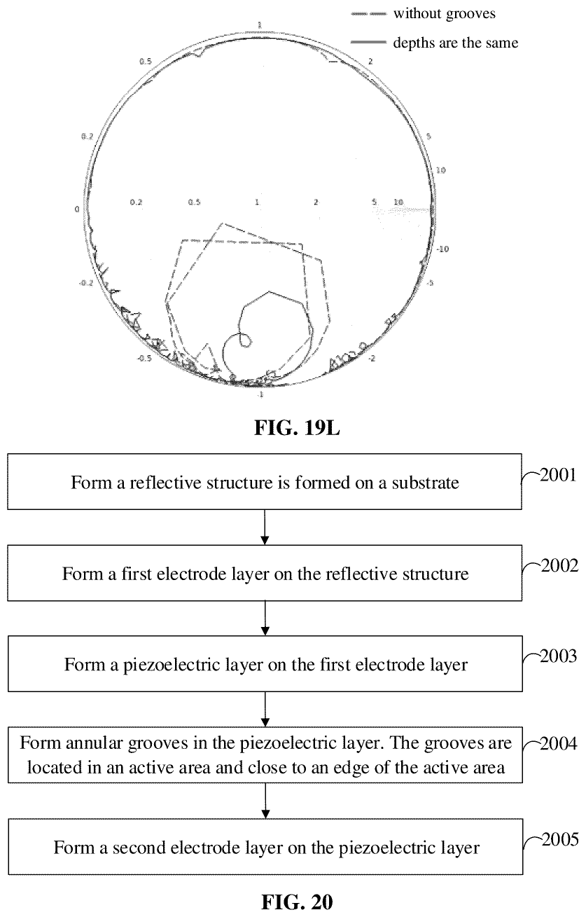

In practical application, FIGS. 19A to 19L illustrates influences on the lateral parasitic mode and the Q when opening depths of the grooves meet different rules according to an embodiment of the present disclosure. Description of FIGS. 19A to 19L can refer to FIGS. 11A to 11O. It should be understood that only one set of grooves are arranged when the opening depths of the multiple grooves 106 are the same in FIGS. 19A to 19L. As can be seen from FIGS. 19A to 19L, compared with the bulk acoustic wave resonator without the grooves, arranging the opening depths of the multiple grooves decreased progressively in the first direction for the bulk acoustic wave resonator can effectively reduce the parasitic resonance, transfer the parasitic resonance to be below the series resonance point, and increase the Q value. When the opening depths of the multiple grooves of the bulk acoustic wave resonator are increased progressively in the first direction, the parasitic resonance can be reduced, but the reduction range is less than a reduction range of the case that the opening depths of the multiple grooves are decreased progressively in the first direction, and the Q can be slightly increased. When the opening depths of the multiple grooves of the bulk acoustic wave resonator are all the same, the parasitic resonance can be reduced and transferred to be below the series resonance point, but the reduction range is less than the reduction range of the case that the opening depths of the multiple grooves are decreased progressively in the first direction, and the Q value can be increased at the same time. That is, when the opening depths of the multiple grooves are decreased progressively in the first direction, the optimal effect of reducing the parasitic resonance and increasing the Q can be achieved.

In the embodiments of the present disclosure, annular grooves are provided at the edge of the active area of the piezoelectric layer. The grooves can prevent transversal shear waves generated by the bulk acoustic wave resonator when stimulated by an electric field from propagating to the external region, limit energy to longitudinal waves in the active area and reduce energy leakage, thereby reducing the parasitic resonance and increasing the Q value.

Based on the above bulk acoustic wave resonance structure, embodiments of the present disclosure further provide a method for manufacturing a bulk acoustic wave resonance structure, which is illustrated in FIG. 20. The method includes the following operations.

At block 2001, a reflective structure is formed on a substrate.

At block 2002, a first electrode layer is formed on the reflective structure.

At block 2003, a piezoelectric layer is formed on the first electrode layer.

At block 2004, at least one annular groove is formed in the piezoelectric layer. The groove is located in an active area and close to an edge of the active area.

At block 2005, a second electrode layer is formed on the piezoelectric layer.

In the above operations of the embodiments of the present disclosure, the method of forming the reflective structure of the bulk acoustic wave resonance structure, the first electrode layer covering the reflective structure, the piezoelectric layer and the second electrode layer in sequence on a surface of the substrate is mature in some implementations. Three examples are described below. It should be noted that the following three examples do not involve manufacturing of the groove in the piezoelectric layer. The manufacturing of the groove in the piezoelectric layer would be described in detail later.

Exemplarily, when the bulk acoustic wave resonance structure includes a first-cavity-type FBAR, the operations of forming the reflective structure on the substrate, forming the first electrode layer on the reflective structure, forming the piezoelectric layer on the first electrode layer and forming the second electrode layer on the piezoelectric layer may include the following operations.

A first reflective sacrificial layer is formed on the surface of the substrate.

The first electrode layer covering the first reflective sacrificial layer is formed.

The piezoelectric layer covering the first electrode layer is formed.

The second electrode layer covering the piezoelectric layer is formed.

The first reflective sacrificial layer is removed, so that a first cavity is formed between the first electrode layer and the substrate based on morphology of the first reflective sacrificial layer, to form the reflective structure.

In the example, the formed bulk acoustic wave resonance structure can refer to the structure other than the grooves 106 in the piezoelectric layer as illustrated in FIG. 8A.

Exemplarily, when the bulk acoustic wave resonance structure includes a second-cavity-type FBAR, the operations of forming the reflective structure on the substrate, forming the first electrode layer on the reflective structure, forming the piezoelectric layer on the first electrode layer and forming the second electrode layer on the piezoelectric layer may include the following operations.

The surface of the substrate is etched to form at least one groove on the surface of the substrate.

A second reflective sacrificial layer filling the groove is formed.

The first electrode layer covering the second reflective sacrificial layer is formed.

The piezoelectric layer covering the first electrode layer is formed.

The second electrode layer covering the piezoelectric layer is formed.

The second reflective sacrificial layer is removed, so that a second cavity is formed between the first electrode layer and the substrate based on morphology of the second reflective sacrificial layer, to form the reflective structure.

In the example, the formed bulk acoustic wave resonance structure can refer to the structure other than the grooves 106 in the piezoelectric layer as illustrated in FIG. 8B.

In practical application, a material of the first reflective sacrificial layer and a material of the second reflective sacrificial layer may include phosphor silicate glass (PSG), silicon dioxide, or the like. When the material is the silicon dioxide, the first reflective sacrificial layer and the second reflective sacrificial layer may be formed through a chemical vapor deposition process by using silane (SiH₄) and oxygen (O₂) as reaction gases.

In practical application, the first reflective sacrificial layer and the second reflective sacrificial layer may be removed through a dry etching process. Specifically, in some embodiments, the dry etching may be vapor etching, and an etching gas may be used to etch the material of the first reflective sacrificial layer and the material of second reflective sacrificial layer. More specifically, when the material of the first reflective sacrificial layer and the material of second reflective sacrificial layer include silicon dioxide, the etching gas may be Hydrogen fluoride (HF) or the like.

Exemplarily, when the bulk acoustic wave resonance structure includes an SMR, the operations of forming the reflective structure on the surface of the substrate, forming the first electrode layer on the reflective structure, forming the piezoelectric layer on the first electrode layer and forming the second electrode layer on the piezoelectric layer may include the following operations.

First dielectric layers and second dielectric layers alternately stacked on the surface of the substrate are formed. Acoustic impedance of the first dielectric layers is different from acoustic impedance of the second dielectric layers.

The first electrode layer covering the alternately stacked first dielectric layer and second dielectric layer is formed.

The piezoelectric layer covering the first electrode layer is formed.

The second electrode layer covering the piezoelectric layer is formed.

In the example, the formed bulk acoustic wave resonance structure can refer to the structure other than the groove(s) 106 in the piezoelectric layer as illustrated in FIG. 8C.

The following describes the formation of the groove(s) in the piezoelectric layer.

In some embodiments, the method further includes the following operations.

The groove(s) is/are filled with an amorphous material.

The second electrode layer is formed on the piezoelectric layer having the groove(s) filled with the amorphous material.

Grooves having different opening orientations and different filling materials can be manufactured by using different methods. In some embodiments, the operation of forming annular groove(s) in the piezoelectric layer may include the following operations.

Annular groove(s) with opening(s) facing a top surface of the piezoelectric layer is formed in the piezoelectric layer, and the groove(s) is/are filled with a sacrificial layer.

After the second electrode layer is formed on the piezoelectric layer, the sacrificial layer is removed so as to fill the groove(s) with air.

That is, when the opening(s) of the groove(s) face(s) the top surface of piezoelectric layer and the groove(s) is/are filled with a solid material such as the amorphous material, the groove(s) can be formed through an etching process in the piezoelectric layer. After the groove(s) is/are filled with the solid material, the second electrode layer is formed on the piezoelectric layer. When the opening(s) of the groove(s) face(s) the top surface of piezoelectric layer and the groove(s) is/are filled with air, the groove(s) need(s) to be formed through the etching process in the piezoelectric layer. Then the sacrificial layer is formed in the groove(s). Then, the second electrode layer is formed on the piezoelectric layer. Finally, the sacrificial layer is removed.

In some other embodiments, the piezoelectric layer includes M piezoelectric sub-layers. M is a positive integer greater than or equal to 2, and is related to a variation rule of opening depth(s) of the groove(s).

The operations of forming the piezoelectric layer on the first electrode layer and forming the annular groove(s) in the piezoelectric layer may include the following operations.

A j-th piezoelectric sub-layer of the M piezoelectric sub-layers is formed in sequence on the first electrode layer, and k annular j-th sub through holes penetrating the j-th piezoelectric sub-layer are formed after each piezoelectric sub-layer is formed. The j-th sub through holes are filled with an amorphous material. j is a positive integer. j is greater than or equal to 1 and is less than or equal to M−1. k is a positive integer, and is related to the number of the groove(s) and the variation rule of the opening depth(s) of the groove(s). Each of (j+1)-th sub through holes is connected to a respective one of the j-th sub through holes.

After forming an (M−1)-th piezoelectric sub-layer of the M piezoelectric sub-layers and filling an (M−1)-th sub through hole, an M-th piezoelectric sub-layer is formed on the (M−1)-th piezoelectric sub-layer so as to form the piezoelectric layer. All sub through holes form the groove(s) together.

That is, when the opening(s) of the groove(s) face(s) a bottom surface of piezoelectric layer and the groove(s) is/are filled with a material comprising the amorphous material, a first manufacturing method may include the following operations. Part of the piezoelectric layer is formed. Through holes penetrating the formed part of the piezoelectric layer are formed. The through holes are completely filled with the amorphous material (the operations of forming part of the piezoelectric layer, punching and stuffing can be repeated for several times according to the variation rules of the opening depth(s) of the groove(s)). Remaining part of the piezoelectric layer can be deposited on the formed part of the piezoelectric layer to get a complete piezoelectric layer. The second electrode layer is formed on the complete piezoelectric layer.

In practical application, the piezoelectric layer can be divided into multiple piezoelectric sub-layers according to the variation rules of the opening depth(s) of the groove(s). The final structure of the groove(s) can be obtained through layer-by-layer growth and layer-by-layer selective perforation. It should be noted that the number of the piezoelectric sub-layers is related to the variation rules of the opening depth(s) of the groove(s). For example, when the opening depths of the grooves are all the same, the number of the piezoelectric sub-layers is 2. When the opening depths of the grooves are decreased or increased progressively in the first direction, the number of the piezoelectric sub-layers is the number of the grooves with different opening depths plus one (the additional one piezoelectric sub-layer is a part without opening at the top of the piezoelectric layer). Each of sub through holes formed in an upper piezoelectric sub-layer is connected to a respective one of sub through holes formed in an upper piezoelectric layer. That is, sub through holes formed in various piezoelectric sub-layers are aligned. The selective perforation in each layer is related to the number of grooves and the variation rules of the opening depths of the grooves. For example, when the opening depths of the three grooves are increased progressively in the first direction, firstly, three first sub through holes are formed in a first piezoelectric sub-layer. When second sub through holes are being formed in a second piezoelectric sub-layer, the second sub through holes are formed on two first sub through holes farther from the edge of the active area. When a third sub through hole is being formed in a third piezoelectric sub-layer, the third sub through hole is formed on a second sub through hole farthest from the edge of the active area. The first sub through holes, the second sub through holes and the third sub through hole form the grooves together.

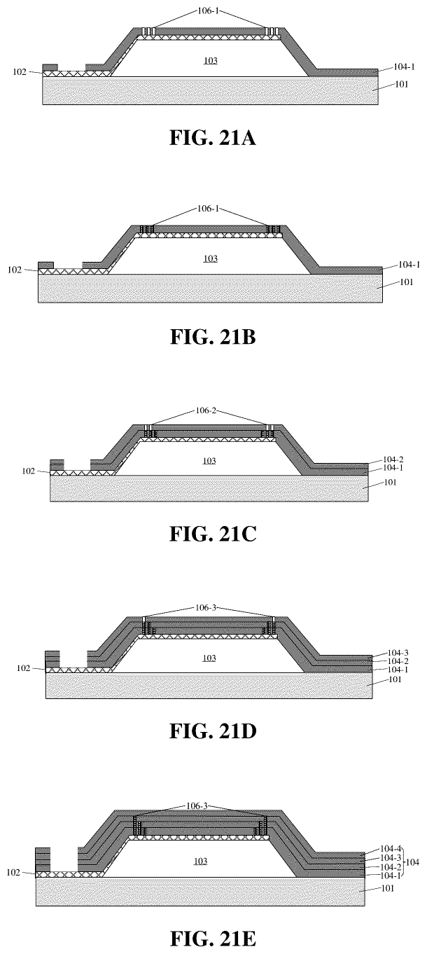

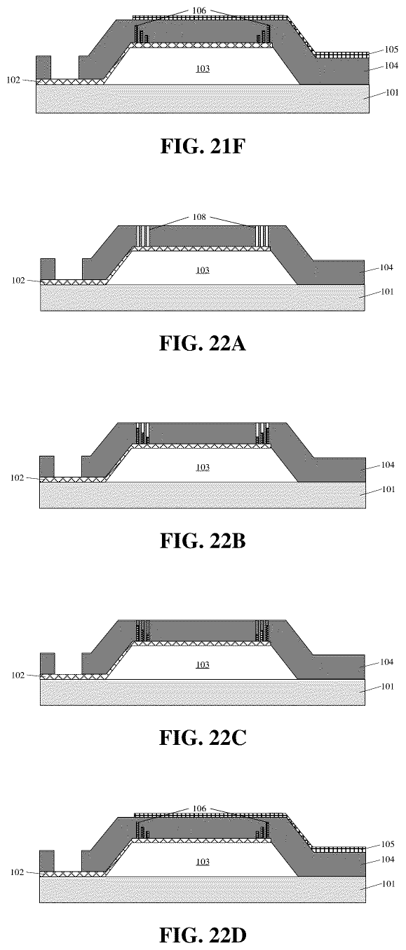

Exemplarily, for the first manufacturing method, detailed description would be made with reference to FIGS. 21A to 21F. In the example, openings of the grooves face the bottom surface of the piezoelectric layer, and the grooves are provided with the amorphous material. The number of the grooves is three, and opening depths of the three grooves are decreased progressively in the first direction. M=4; j=1, 2, 3; k=3, 2, 1.

The operations that the piezoelectric layer is formed on the first electrode layer and the annular grooves are formed in the piezoelectric layer may include the following operations.

As illustrated in FIG. 21A, the first piezoelectric sub-layer 140-1 is formed on the first electrode layer, and three annular first sub through holes 160-1 penetrating the first piezoelectric sub-layer are formed. As illustrated in FIG. 21B, the three first sub through holes 160-1 are filled with the amorphous material. As illustrated in FIG. 21C, the second piezoelectric sub-layer 140-2 is formed on the first piezoelectric sub-layer 140-1, and two annular second sub through holes 160-2 penetrating the second piezoelectric sub-layer 140-2 are formed. Each of the two second sub through holes 160-2 extends to a respective first sub through holes 160-1 (the two annular second sub through holes 160-2 extends to two first sub through holes 160-1 close to the edge of the active area).

As illustrated in FIG. 21D, the two second sub through holes 160-2 are filled with the amorphous material. As illustrated in FIG. 21D, the third piezoelectric sub-layer 140-3 is formed on the second piezoelectric sub-layer 140-2, and one annular third sub through hole 160-3 penetrating the third piezoelectric sub-layer 140-3 is formed. The third sub through hole 160-3 extends to a corresponding second sub through hole 160-2 (the one annular third sub through hole 160-3 extends to a second sub through hole 160-2 closest to the edge of the active area).

As illustrated in FIG. 21E, the third sub through hole 160-3 is filled with the amorphous material. As illustrated in FIG. 21E, the fourth piezoelectric sub-layer 140-4 is formed on the third piezoelectric sub-layer 140-3. The first piezoelectric sub-layer 140-1, the second piezoelectric sub-layer 140-2, the third piezoelectric sub-layer 140-3 and the fourth piezoelectric sub-layer 140-4 form the piezoelectric layer 140 together. The first sub through holes 160-1, the second sub through holes 160-2 and the third sub through hole 160-3 form the grooves 160 together.

As illustrated in FIG. 21F, the second electrode layer 105 is formed on the piezoelectric layer 104.

In some other embodiments, before that the second electrode layer is formed on the piezoelectric layer, the method further includes the following operations.

Annular through holes penetrating the piezoelectric layer are formed.

The annular through holes are filled with the amorphous material to a preset height. The preset height is related to the variation rule of the opening depths of the grooves.

The annular through holes are continuously filled with a same material as a material of the piezoelectric layer until top surfaces of the annular through holes are flush with a top surface of the piezoelectric layer.

That is, when the openings of the grooves face the bottom surface of piezoelectric layer and the grooves are filled with the solid material such as the amorphous material, a second manufacturing method may include the following operations. A complete piezoelectric layer is formed, and through holes penetrating the complete piezoelectric layer is formed. The through holes are partially filled with the amorphous material. That is, the through holes are filled with the amorphous material to the preset height (the preset height refers to the opening depths of the grooves). Remaining part of the through holes is filled with the same material as the piezoelectric layer. The second electrode layer is formed on the complete piezoelectric layer.

Exemplarily, for the second manufacturing method, detailed description would be made with reference to FIGS. 22A to 22F. In the example, the openings of the grooves face the bottom surface of the piezoelectric layer, and the grooves are provided with the amorphous material. The number of the grooves is three, and the opening depths of the three grooves are decreased progressively in the first direction.

Before the second electrode layer 105 is formed on the piezoelectric layer 104, the method further includes the following operations.

As illustrated in FIG. 22A, three annular through holes penetrating the piezoelectric layer 104 are formed. As illustrated in FIG. 22B, each of the three through holes is filled with the amorphous material to a height that is the same as a respective one of the opening depths of the three grooves (which are decreased progressively in the first direction). As illustrated in FIG. 22C, the three through holes are continuously filled with the same material as the material of the piezoelectric layer until the top surfaces of the three through holes are flush with the top surface of the piezoelectric layer 104. As illustrated in FIG. 22D, the second electrode layer 105 is formed on the piezoelectric layer 104.

It should be noted that FIGS. 22A to 22D merely illustrate the manufacturing process of the three grooves having the opening depths decreased progressively in the first direction. It can be understood that when the opening depths of the three grooves are increased progressively in the first direction, each of the three through holes is filled with the amorphous material to a height that is the same as a respective one of the opening depths of the three grooves (which are increased progressively in the first direction).

Based on the above description of the methods, the grooves are located in the middle of the piezoelectric layer, which can be realized by adding one piezoelectric sub-layer on the basis of the three embodiments and would not be repeated here.

In the embodiments of the present disclosure, it should be understood that the disclosed apparatuses, systems and methods can be implemented in other ways. The foregoing description is merely a specific embodiment of the present disclosure, but the scope of protection of the present disclosure is not limited to this. Any change or replacement readily contemplated by those skilled in the art within the technical scope disclosed in the present disclosure shall fall within the scope of protection of the present disclosure. Accordingly, the scope of protection of the present disclosure shall be subject to the scope of protection of the claims.

What is claimed is:

1. A bulk acoustic wave resonance structure, comprising:
a substrate; and
a reflective structure, a first electrode layer, a piezoelectric layer and a second electrode layer stacked on the substrate in sequence, wherein the piezoelectric layer is provided with at least one annular groove, and the at least one annular groove is located in an active area and close to an edge of the active area.

2. The bulk acoustic wave resonance structure of claim 1, wherein an outer contour of the at least one annular groove comprises a closed shape, and the closed shape comprises a curve and two or more straight lines.

3. The bulk acoustic wave resonance structure of claim 1, wherein the at least one annular groove comprises a plurality of grooves; the plurality of grooves are arranged in sequence in a first direction, and the first direction comprises a direction from the edge of the active area to middle of the active area.

4. The bulk acoustic wave resonance structure of claim 3, wherein a number of the plurality of grooves is three.

5. The bulk acoustic wave resonance structure of claim 3, wherein opening depths of the plurality of grooves are smaller than a thickness of the piezoelectric layer; and wherein the opening depths of the plurality of grooves are decreased progressively in the first direction, or increased progressively in the first direction, or partially the same, or all the same.

6. The bulk acoustic wave resonance structure of claim 5, wherein the opening depths of the plurality of grooves are decreased progressively in the first direction.

7. The bulk acoustic wave resonance structure of claim 6, wherein a number of the plurality of grooves is N, and an i-th groove of the N grooves in the first direction has an opening depth of (N−i+1)×H/(N+1); and
wherein N is a positive integer greater than 1, i is a positive integer greater than or equal to 1 and less than or equal to N, and H is the thickness of the piezoelectric layer.

8. The bulk acoustic wave resonance structure of claim 5, wherein the opening depths of the plurality of grooves are increased progressively in the first direction; a number of the plurality of grooves is N, and an i-th groove of the N grooves in the first direction has an opening depth of i×H/(N+1); and
wherein N is a positive integer greater than 1, i is a positive integer greater than or equal to 1 and less than or equal to N, and H is the thickness of the piezoelectric layer.

9. The bulk acoustic wave resonance structure of claim 5, wherein the opening depths of the plurality of grooves are the same; the opening depths of the plurality of grooves range from 1/2H to H, and H is the thickness of the piezoelectric layer.

10. The bulk acoustic wave resonance structure of claim 3, wherein each of the plurality of grooves comprises a plurality of sub grooves; the plurality of sub grooves form an annular shape together, and opening depths of the plurality of sub grooves are the same.

11. The bulk acoustic wave resonance structure of claim 10, wherein cross-section of each of the plurality of sub grooves is of a rectangular shape, a circular shape or an oval shape.

12. The bulk acoustic wave resonance structure of claim 10, wherein both opening widths of the plurality of sub grooves and spacings between adjacent sub grooves are different from an integer multiple of a half wavelength of a higher harmonic of a lateral wave generated in the piezoelectric layer, and
wherein the opening widths of the plurality of sub grooves range from 0.05 μm to 10 μm, and the spacings between adjacent sub grooves range from 0.05 μm to 10 μm.

13. The bulk acoustic wave resonance structure of claim 1, wherein an opening of the at least one groove faces a top surface of the piezoelectric layer; or the opening of the at least one groove faces a bottom surface of the piezoelectric layer; or the at least one groove is located in middle of the piezoelectric layer.

14. The bulk acoustic wave resonance structure of claim 1, wherein the at least one groove is provided with a filling material, and a difference between an acoustic impedance of the filling material and an acoustic impedance of a material of the piezoelectric layer is greater than a preset value,
wherein the filling material in the at least one groove comprises air or an amorphous material.

15. The bulk acoustic wave resonance structure of claim 1, wherein the second electrode layer is provided with a frame having an annular three-dimensional structure, and the frame is located in the active area and close to the edge of the active area.

16. A method for manufacturing a bulk acoustic wave resonance structure, comprising:
forming a reflective structure on a substrate;
forming a first electrode layer on the reflective structure;
forming a piezoelectric layer on the first electrode layer;
forming annular grooves in the piezoelectric layer, wherein the grooves are located in an active area and close to an edge of the active area; and
forming a second electrode layer on the piezoelectric layer.

17. The method for manufacturing the bulk acoustic wave resonance structure of claim 16, further comprising:
filling the grooves with an amorphous material; and
forming the second electrode layer on the piezoelectric layer having the grooves filled with the amorphous material.

18. The method for manufacturing the bulk acoustic wave resonance structure of claim 16, wherein forming the annular grooves in the piezoelectric layer comprises:
forming, in the piezoelectric layer, annular grooves with openings facing a top surface of the piezoelectric layer, and filling the grooves with a sacrificial layer,
wherein the method further comprises:
after forming the second electrode layer on the piezoelectric layer, removing the sacrificial layer so as to fill the grooves with air.

19. The method for manufacturing the bulk acoustic wave resonance structure of claim 16, wherein the piezoelectric layer comprises M piezoelectric sub-layers, M being a positive integer greater than or equal to 2, and M being related to a variation rule of opening depths of the grooves,
wherein forming the piezoelectric layer on the first electrode layer and forming the annular grooves in the piezoelectric layer comprises:
forming a j-th piezoelectric sub-layer of the M piezoelectric sub-layers in sequence on the first electrode layer, forming k annular j-th sub through holes penetrating the j-th piezoelectric sub-layer after forming each piezoelectric sub-layer, and filling the j-th sub through holes with an amorphous material, wherein j is a positive integer; j is greater than or equal to 1 and is less than or equal to M−1; k is a positive integer, and is related to a number of the grooves and the variation rule of the opening depths of the grooves, and each of (j+1)-th sub through holes is connected to a respective one of the j-th sub through holes;
after forming a (M−1)-th piezoelectric sub-layer of the M piezoelectric sub-layers and filling (M−1)-th sub through holes, forming M-th piezoelectric sub-layer on the (M−1)-th piezoelectric sub-layer so as to form the piezoelectric layer, wherein all sub through holes form the grooves together.

20. The method for manufacturing the bulk acoustic wave resonance structure of claim 16, wherein before forming the second electrode layer on the piezoelectric layer, the method further comprises:
forming annular through holes penetrating the piezoelectric layer;
filling the annular through holes with an amorphous material to a preset height, wherein the preset height is related to a variation rule of opening depths of the grooves; and
continuously filling the annular through holes with a same material as a material of the piezoelectric layer until top surfaces of the annular through holes are flush with a top surface of the piezoelectric layer.
